(19) United States
(12) Patent Application Publication
(10) Pub. No.: US 2026/0121378 A1
(43) Pub. Date: Apr. 30, 2026

(54) OPTICAL LINKS WITH DEGREE OF FREEDOM VCSEL MODULATION ON A PHOTONIC WAFER-SCALE INTERPOSER

(71) Applicant: Volantis Semiconductor, Inc., Portland, OR (US)

(72) Inventor: Tapabrata Ghosh, San Francisco, CA (US)

(73) Assignee: Volantis Semiconductor, Inc., Portland, OR (US)

(21) Appl. No.: 19/235,870

(22) Filed: Jun. 12, 2025

Related U.S. Application Data
(63) Continuation-in-part of application No. 19/230,233, filed on Jun. 6, 2025.
Application No. 19/230,233 is a continuation-in-part of application No. 19/223,614, filed on May 30, 2025.
Application No. 19/223,614 is a continuation-in-part of application No. 19/222,606, filed on May 29, 2025.
Application No. 19/222,606 is a continuation-in-part of application No. 19/211,446, filed on May 19, 2025.
Application No. 19/211,446 is a continuation-in-part of application No. 19/210,116, filed on May 16, 2025.
Application No. 19/210,116 is a continuation-in-part of application No. 19/192,587, filed on Apr. 29, 2025.
Application No. 19/192,587 is a continuation-in-part of application No. 19/192,146, filed on Apr. 28, 2025.
Application No. 19/192,146 is a continuation-in-part of application No. 19/189,471, filed on Apr. 25, 2025.
Application No. 19/189,471 is a continuation-in-part of application No. 19/188,057, filed on Apr. 24, 2025.
Application No. 19/188,057 is a continuation-in-part of application No. 19/177,834, filed on Apr. 14, 2025.
Application No. 19/177,834 is a continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. H01S 5/042; H01S 5/10; H01S 5/183

(52) U.S. Cl. CPC H01S 5/0427; H01S 5/101; H01S 5/18305

(57) ABSTRACT

A plurality of circuits, which can be chiplets, and a plurality of vertical-cavity surface-emitting lasers (VCSELs) are bonded to a front side of a photonic wafer-scale interposer (PWSI). The PWSI includes a plurality of waveguides. A first circuit sends electrical data to a first VCSEL. A degree of freedom (DoF) of a light beam emitted by the VCSEL is modulated. The emitted light beam comprises a degree of freedom modulated beam (DFMB). The degree of freedom includes a polarization, a mode, or a wavelength. The DFMB is based on the electrical data that was sent. The DFMB is coupled to a waveguide. The waveguide is further coupled to an optical decoding element. The optical decoding element decodes the DFMB into the electrical data. The electrical data that was decoded is delivered to a second circuit.

### RELATED APPLICATIONS

This application is a continuation-in-part of U.S. patent application “Optical Link With VCSEL Wavelength Modulation” Ser. No. 19/230,233, filed Jun. 6, 2025.

The U.S. patent application “Optical Link With VCSEL Wavelength Modulation” Ser. No. 19/230,233, filed Jun. 6, 2025, is also a continuation-in-part of U.S. patent application “Optical Link With Modulation Of VCSEL Modes” Ser. No. 19/223,614, filed May 30, 2025.

The U.S. patent application “Optical Link With Modulation Of VCSEL Modes” Ser. No. 19/223,614, filed May 30, 2025, is also a continuation-in part of U.S. patent application “Optical Link With Polarization-Switched VCSEL Modulation” Ser. No. 19/222,606, filed May 29, 2025.

The U.S. patent application “Optical Link With Polarization-Switched VCSEL Modulation” Ser. No. 19/222,606, filed May 29, 2025, is also a continuation-in-part of U.S. patent application “Hierarchical Redundancy With Parallel Optical Links” Ser. No. 19/211,446, filed May 19, 2025.

The U.S. patent application “Hierarchical Redundancy With Parallel Optical Links” Ser. No. 19/211,446, filed May 19, 2025, is also a continuation-in-part of U.S. patent application “Waveguides Based On Nanoimprint Lithography On A Photonic Wafer Scale Interposer” Ser. No. 19/210,116, filed May 16, 2025.

The U.S. patent application “Waveguides Based On Nanoimprint Lithography On A Photonic Wafer Scale Interposer” Ser. No. 19/210,116, filed May 16, 2025, is also a continuation-in-part of U.S. patent application “Photonic Wafer-Scale Interposer With Mirrors Based on Nanoimprint Lithography” Ser. No. 19/192,587, filed Apr. 29, 2025.

The U.S. patent application “Photonic Wafer-Scale Interposer With Mirrors Based on Nanoimprint Lithography” Ser. No. 19/192,587, filed Apr. 29, 2025, is also continuation-in-part of U.S. patent application “Photonic Wafer-Scale Interposer With Micro Transfer Printed VCSELS And Back Side Power Delivery” Ser. No. 19/192,146, filed Apr. 28, 2025.

The U.S. patent application “Photonic Wafer-Scale Interposer With Micro Transfer Printed VCSELS And Back Side Power Delivery” Ser. No. 19/192,146, filed Apr. 28, 2025, is also a continuation-in-part of U.S. patent application “Photonic Wafer Scale Interposer With Integrated Crystallographic Etched Mirrors And Pre-Angled Light” Ser. No. 19/189,471, filed Apr. 25, 2025.

The U.S. patent application “Photonic Wafer Scale Interposer With Integrated Crystallographic Etched Mirrors And Pre-Angled Light” Ser. No. 19/189,471, filed Apr. 25, 2025, is also a continuation-in-part of U.S. patent application “Photonic Wafer Scale Interposer With Angled Beam Grating Couplers” Ser. No. 19/188,057, filed Apr. 24, 2025.

The U.S. patent application “Photonic Wafer Scale Interposer With Angled Beam Grating Couplers” Ser. No. 19/188,057, filed Apr. 24, 2025, is also a continuation-in-part of U.S. patent application “Back Side Power Delivery For Wafer-Scale Integration With An Isometric Grid Array With Compression Pins” Ser. No. 19/177,834, filed Apr. 14, 2025.

The U.S. patent application “Back Side Power Delivery For Wafer-Scale Integration With An Isometric Grid Array With Compression Pins” Ser. No. 19/177,834, filed Apr. 14, 2025, is also a continuation-in-part of U.S. patent application “Back Side Power Delivery For Wafer-Scale Integration With Laser Assisted Bonding” Ser. No. 19/093,546, filed Mar. 28, 2025.

The U.S. patent application “Back Side Power Delivery For Wafer-Scale Integration With Laser Assisted Bonding” Ser. No. 19/093,546, filed Mar. 28, 2025, is also a continuation-in-part of U.S. patent application “Photonic Wafer-Scale Interposer With Tapered Waveguides” Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive” Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling For Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025, is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024, is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling” Ser. No. 63/714,353, filed Oct. 31, 2024.

Each of the foregoing applications is hereby incorporated by reference in its entirety.

### FIELD OF ART

This application relates generally to transmitting data and more particularly to optical links with degree of freedom VCSEL modulation on a photonic wafer-scale interposer.

### BACKGROUND

Techniques and the technologies for the storage and dissemination of information have evolved over millennia. From time immemorial, interhuman communication has been based on facial expressions, vocalizations, and gestures. But such communication fails when those involved cannot see each other. Further, visual and oral communications are transitory. The invention of writing enabled information storage and dissemination. Whether a cave painting depicting a hunt or major event, symbols that represented words and concepts, or an alphabet that enabled the recoding of words, writing enabled humans to store and share information. Thus, techniques and technologies have emerged that enable information storage and exchange between humans who are face to face, located in different locations on Earth, or even beyond.

The exchange of written material addressed information storage and dissemination, but writing was slow and prone to error. Recording important information required transcribing that information based on personal experience, gathered from oral exchanges, and so on. The transcriptions were unique. Obtaining a copy of the information required tediously writing the copy by hand. The invention of printing press greatly improved the exchange of written material by enabling the mass creation of copies. Material ranging from the sublime Gutenberg Bible to ridiculous satirical materials could be produced and distributed on a large scale. Such materials could be stored and carried locally and transported to other locations. However, disseminating information over long distances could still be slow. Having to walk or ride to even a nearby village or town could take hours or days. While this delay was tolerable for transporting materials such as books, time-critical information regarding fire or enemy attacks arrived too late to be of use. Timely information delivery was greatly improved with the development of electrically based communications such as the telegraph, telephone, and later, radio and television. These technologies enabled rapid communication across distances ranging from across town to between continents.

The invention of digital communications has supported worldwide, immediate exchange of data including text, telephony, and video. These applications leveraged previous technologies such as telephone and cable and supplemented them with optical cables that carry data as light at previously unattainable speeds. Wireless technologies have also evolved with the rollout of advanced cellular technologies such as 5G for voice and Internet. Further technologies continue to be developed including cloud computing for data storage and processing. Such technologies further support increasing demands for faster, lower latency systems and networks. Each of these new and emerging technologies benefits from advances in system configurations, chip architectures, and memory structures, among many other improvements. These improvements appear in accelerators, high performance processors, systems-on-chip (SoCs), and communications structures, naming a mere few. The emerging technologies further benefit applications that are extremely computationally intensive including AI and modeling applications. Human communication has come a great distance from facial expressions, vocalizations, and gestures. Further communications advances will both enable new applications and continue to be driven by them.

### SUMMARY

The demand for increased processor performance has grown significantly. Applications such as artificial intelligence (AI), climate modeling, genome sequencing, and so on continue to strain current processing technology capabilities. The processing technology that is strained includes processors, systems-on-chip (SoCs), accelerators, transformers, servers, memory, power delivery, cooling technologies, and so on. Additional processing capabilities are desperately needed. For example, today's large language model (LLM) training time can be measured in months, even when the training is executing on many processors and accelerators that are running 24×7. Making further computational improvements will require advances in all system components. For example, accelerators, memory, interconnections between processors, and so on must keep pace with the ability of the processing elements to perform calculations. If the system components are unable to keep pace, then the processing elements can be starved for data and can stall. The overall result from a lack of improvement to the system elements would be that little, if any, overall performance improvement would be achieved. Communication bandwidth, speed (latency), and power are critical to overall system performance, both in today's high performance systems and the systems that will be created in the future.

Disclosed techniques enable improved data transmissions. The data transmissions are based on optical links with degree of freedom VCSEL modulation on a photonic wafer-scale interposer. Circuits, which can be chiplets, and vertical-cavity surface-emitting lasers (VCSELs), are bonded to a photonic wafer-scale interposer (PWSI). The PWSI includes waveguides that can be used for transmitting data between chips. A first circuit, which can be a first chiplet, sends electrical data. The electrical data is sent to a vertical-cavity surface-emitting laser (VCSEL). A light beam is emitted by the VCSEL, where the light is modulated based on a degree of freedom (DoF). The emitted light beam includes a degree of freedom modulated beam (DFMB). The DFMB is coupled optically to a waveguide. The coupling optically can be accomplished using a grating coupler, a mirror, a bent waveguide, or an off-axis diffractive lens. The waveguide is further coupled to an optical decoding element (ODE). The ODE decodes the DFMB into the electrical data. The decoded electrical data is delivered to a second circuit, which can be a second chiplet.

A method for transmitting data is disclosed comprising: bonding, to a front side of a photonic wafer-scale interposer (PWSI), a plurality of circuits and a plurality of vertical-cavity surface-emitting lasers (VCSELs), wherein the PWSI includes a plurality of waveguides; sending electrical data, by a first circuit within the plurality of circuits, to a first VCSEL within the plurality of VCSELs; modulating a degree of freedom (DoF) of a light beam emitted by the first VCSEL, wherein the emitted light beam comprises a degree of freedom modulated beam (DFMB), wherein the DFMB is based on the electrical data that was sent; coupling optically the DFMB to a waveguide within the plurality of waveguides, wherein the waveguide is further coupled to an optical decoding element; decoding, by the optical decoding element, the DFMB into the electrical data; and delivering the electrical data that was decoded to a second circuit within the plurality of circuits.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for optical links with degree of freedom VCSEL modulation on a photonic wafer-scale interposer.

FIG. 2 is a flow diagram for degree of freedom modulation.

FIG. 3 is a cross-section of a VCSEL.

FIG. 4 is a block diagram of an optical link with degree of freedom VCSEL modulation.

FIG. 5 is a diagram for asymmetric current injection for polarization modulation.

FIG. 6 is a diagram of transverse electromagnetic (TEM) modes.

FIG. 7 is a cross-section of a VCSEL with a tuning region for wavelength modulation.

FIG. 8 is an apparatus for an optical link with degree of freedom VCSEL modulation.

FIG. 9 is a system diagram for optical links with degree of freedom VCSEL modulation on a photonic wafer-scale interposer.

### DETAILED DESCRIPTION

Techniques for transmitting data using optical links with degree of freedom VCSEL modulation on a photonic wafer-scale interposer are disclosed. Today's rapidly increasing demand for processing performance continues to tax the capabilities of existing processors and other system elements. To meet these demands, high performance systems-on-chip (SoCs) have been designed that can include processors, memories, switching elements, cores, and so on. These SoCs can feature transistor counts in the tens of billions. To further advance the vanguard of system-level performance, accelerators, such as artificial intelligence (AI) accelerators, have been designed to offload and accelerate particularly challenging calculations. For example, today's large language models (LLMs) can rely on many such scaled-out accelerators to perform model training and inferencing. As raw processing power increases, the need for additional bandwidth and speed for accessing memory elements also increases, leading to advancements such as HBM memories where memory dies can be stacked on a single substrate.

The relentless need for increased performance has also spurred innovation in methods to interconnect system elements. In the now distant past, simple bus architectures such as the Peripheral Component Interconnect (PCI) bus enabled sufficient bandwidth to keep processor elements from stalling. However, as these system elements grew both physically and in their ability to process more data more efficiently, additional methods of interconnect were developed. For example, high speed serial links such as PCI Express (PCIe) enabled Gigabit-per-second speeds on multiple “lanes.” As processing power has increased, optical communications have become a low power, high bandwidth alternative for transferring data between processing elements. For example, multimode fibers enable remarkably high bandwidth, short-reach optical links which can be used between server racks, switches, storage, and so on.

Optical interconnect solutions have also been researched and developed to increase on-chip communications. For example, vertical-cavity surface-emitting lasers (VCSELS) can be used to generate light-based communication with a chip, wafer, etc. with lower latency and better bandwidth than traditional metal paths, especially when those paths are long. However, VCSELS have disadvantages which can limit their performance and increase power usage. Traditionally, current is used to modulate a VCSEL. That is, once the VCSEL lases and light is emitted, the intensity of the light can be adjusted by adding additional current. The optical power difference required to recognize a “1” (e.g., “on”) as opposed to a “0” (e.g., “off”) can be described as the extinction ratio of the VCSEL. A high extinction ratio is helpful for signal quality, ease of receiver sensing, and power usage. However, technical issues exist that can hinder and limit the effectiveness of VCSELs as on-chip, on-wafer, on-interposer, etc. communication devices. First, VCSELs can be associated with a threshold current, that is, a minimum level of current which must be sent into the active area of the VCSEL before the VCSEL lases and light can be emitted. This threshold current can reduce the extinction ratio and increase power usage. Further, while optical power output (e.g., light intensity) of the VCSEL near the threshold can be linear, the power output can become non-linear as current is increased. Thus, modulating VCSEL intensity based on current can lead to increased power usage to maintain a high extinction ratio, especially when many VCSELS are incorporated in a chip, wafer, interposer, and so on.

To address these issues, optical links with degree of freedom VCSEL modulation on a photonic wafer-scale interposer are disclosed. A plurality of circuits and a plurality of VCSELs are bonded to a front side of a photonic wafer-scale interposer (PWSI). The PWSI further includes a plurality of waveguides that can be used for transmitting data. Electrical data is sent by a first circuit to a vertical-cavity surface-emitting laser (VCSEL). The first circuit can be a chiplet, an SoC, a wafer, an ASIC, a core, a core on a wafer, and so on. The first circuit can be a circuit within a chip, a chiplet, a system-on-chip (SoC), a wafer, etc. A degree of freedom of the VCSEL is modulated. The degree of freedom can include a polarization of light, a light mode, a light wavelength, and so on. The VCSEL emits a degree of freedom modulated beam (DFMB). The DFMB is based on the electrical data that was sent. The DFMB is coupled optically to a waveguide. The DFMB can be coupled optically to other optical media such as an optical fiber. The coupling optically can be accomplished by a mirror, such as a TMAH-etched mirror, a grating coupler, and so on. The coupling can include angling the DFMB that was emitted by the VCSEL. The angling can be based on a micro-optical element (MOE) such as a micro lens, a diffractive optical element, a Fresnel lens, an asymmetric non-focusing optical device, and so on.

The waveguide is further coupled to an optical decoding element (ODE). The ODE can comprise a grating coupler, a polarization filter, a polarization multiplexor (PMUX), and so on. The ODE decodes the DFMB into the electrical data. In the case of a PMUX, a polarized beam splitter (PBS) can separate the DFMB into at least two polarized optical signals. The PBS can be within the PMUX. The separating can be based on a plane of polarization of the polarization-modulated beam (PMB). Each polarized optical signal, optical mode, or optical wavelength can be transformed by a unique photodiode. The transforming can result in at least two electrical signals. These electrical signals can be assembled into a single electrical signal. The single electrical signal can comprise the electrical data that was sent. The electrical data that was decoded is delivered to a second circuit, which can be a chiplet, an SoC, a wafer, an ASIC, a core, a core on a wafer, and so on. The second circuit can comprise a circuit within a chip, a chiplet, an SoC, a wafer, etc. The first chiplet, the second chiplet, and the VCSEL can be within a plurality of chiplets bonded to a front side of a photonic wafer-scale integrations interposer (PWSI). The PWSI can include a plurality of waveguides. The waveguide can comprise a waveguide within the plurality of waveguides. Other optical media can be used. The optical medium can include an optical fiber.

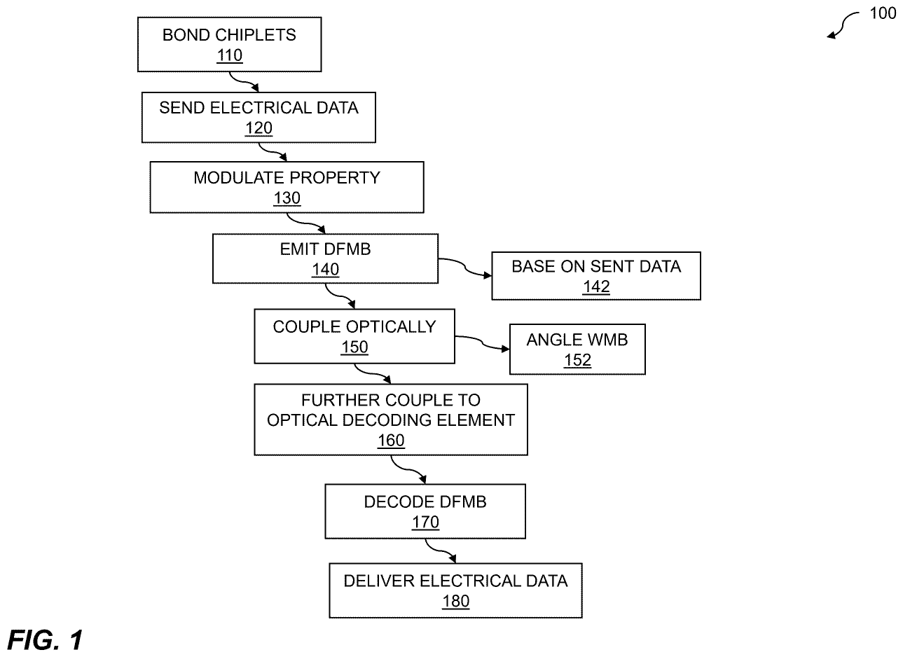

FIG. 1 is a flow diagram for optical links with degree of freedom VCSEL modulation on a photonic wafer-scale interposer. The flow 100 includes bonding chiplets 110. Embodiments include bonding, to a front side of a photonic wafer-scale interposer (PWSI), a plurality of circuits and a plurality of vertical-cavity surface-emitting lasers (VCSELs), wherein the PWSI includes a plurality of waveguides. The plurality of circuits can include chiplets that perform a variety of functions such as artificial intelligence (AI) acceleration, switching, data processing of various data types, and so on. The plurality of circuits can include cores such as processor cores, cores fabricated on or coupled to a wafer, and the like. The PWSI includes a plurality of waveguides. The waveguides can be used to transmit data between circuits. In embodiments, at least one waveguide in the plurality of waveguides comprises a first distance, wherein the first distance is greater than an exposure, on the PWSI, of a single photomask reticle. In some embodiments, the at least one waveguide is fabricated using a nanoimprint lithography (NIL) process. To accommodate longer paths, the waveguides can be manufactured via another suitable fabrication technology. In a usage example, fabricating the plurality of waveguides can be accomplished with techniques that are not based on reticle stitching.

The flow 100 includes sending electrical data 120. Embodiments include sending electrical data, by a first circuit within the plurality of circuits, to a first VCSEL within the plurality of VCSELs. The first circuit can be a circuit within a chip, a core, a chiplet, an SoC, a wafer, an interposer, etc. The first circuit can comprise a processor, a chiplet, a multi-core processor, a memory controller, a memory chip such as double date rate (DDR) or high bandwidth memory (HBM), an input/output (I/O) chip, an AI accelerator, a switching chip, and so on. The first circuit can further comprise a core, a core on (or manufactured within) a wafer, etc. The first circuit and the first VCSEL can be on the same or different circuit boards, interposers, wafers, etc. Noted previously, the first circuit and the first VCSEL can be bonded to a front side of the photonic wafer-scale interposer. The sending can be accomplished using any means to communicate between chips. For example, the sending can be based on a routes on a printed circuit board, a bus interface, a wireless communication protocol such as Bluetooth™, metal layers on a wafer or a wafer interposer, and so on. The electrical data can comprise serialized data, data packets, handshaking signals, etc.

A VCSEL can be a semiconductor laser fabricated on a chip. The first VCSEL can comprise a VCSEL array. The VCSEL array can include a plurality of VCSELs. The fabrication can be based on gallium arsenide or another suitable material. The first VCSEL can emit light in a direction perpendicular to the chip. The direction can be up (e.g., away from the chip) or down (e.g., into the chip). When light is emitted down, a window can be provided so that the light can escape through the back of the chip. To aid projection of the light, the substrate of the chip can be thinned. The light that is emitted can be coherent light that is in a wavelength range, such as 850 nm-950 nm. Other ranges are possible.

The flow 100 includes modulating a property of light 130. The property of light that is modulated includes a degree of freedom (DoF) of a light beam emitted by the first VCSEL. Embodiments include modulating a degree of freedom (DoF) of a light beam emitted by the first VCSEL, wherein the emitted light beam comprises a degree of freedom modulated beam (DFMB), wherein the DFMB is based on the electrical data that was sent. The modulating a degree of freedom can include modulating a polarization of the first VCSEL, modulating a mode of the first VCSEL, modulating a wavelength of the first VCSEL, modulating an intensity of the first VCSEL, and so on. The modulating a property of the light causes the first VCSEL to emit a light beam based on the degree of freedom. The resulting emitted light beam comprises a degree of freedom modulated beam (DFMB). The DFMB can include one or more of a polarization of light, a mode of light, a wavelength of light, an intensity of light, etc. The DFMB is based on the electrical data that was sent.

The modulating can be based on multiplexing techniques such as a time division multiplexing (TDM) technique. The TDM technique can enable sending of multiple degree of freedom signals by assigning a time slot to each degree of freedom signal. Modulation can include adjusting properties of light emission of the first VCSEL to encode optical data. For example, modulation can be based on current. Adjusting the current applied to an active region of the first VCSEL can turn light emission on/off or change the intensity of the emitted light. When the current is below a threshold, lasing action can be stopped. When current levels return to a level exceeding the threshold, lasing can restart. As current is increased, a brightness, or optical power, of the first VCSEL can be increased. The detection of a presence or absence of light from the first VCSEL can be used to encode a “1” or “0” in the form of a light wave.

Modulation can include changing properties of the light that is emitted. For example, modulation can include one or more degrees of freedom, where a degree of freedom can include a mode, a polarization, a wavelength, and so on. Modulation can also include changing a degree of freedom, during transmission, of the light emitted by the first VCSEL. In embodiments, the degree of freedom comprises a polarization of the first VCSEL. Polarization can refer to an orientation of an oscillating light wave. The polarization can include linear polarization, circular polarization, elliptical polarization, etc. In some embodiments, the degree of freedom comprises a mode of the first VCSEL. The degree of freedom can include a mode such a transverse electromagnetic (TEM) mode. In a usage example, the TEM mode can include TEM₀₀, TEM₁₀, and TEM₀₁. In other embodiments, the degree of freedom comprises a wavelength of the first VCSEL. The degree of freedom can include a wavelength of light.

Various methods of VCSEL modulation can change the degree of freedom of light that is emitted. In embodiments, the modulation is based on asymmetric current injection. Asymmetric current injection can include sending current into an active region of the first VCSEL in a non-uniform way. The non-uniformity can influence the first VCSEL to produce polarized light in a first direction. The applied current can be altered to produce polarized light in a second direction. The asymmetric current injection can include a current with a DC offset, a current that includes an asymmetric wave, and the like. In some embodiments, the first VCSEL includes a ferroelectric liquid crystal layer (FLC). The FLC can include liquid crystals that can be oriented by an electric field. Applying a voltage to the FLC can influence the polarization of light emitted by the VCSEL. In a usage example, the first VCSEL can include an FLC. The FLC can include a bottom and middle Distributed Bragg Reflector (DBR) with the FLC layer on top of the middle layer. A top DBR can be included on top of the FLC layer. Other layouts are possible.

In other embodiments, the modulating comprises altering current to the first VCSEL. The altering current can enable degrees of freedom based on modes. The modes can include transverse electromagnetic (TEM) modes. The TEM modes can include a fundamental mode, a low order mode, a high order mode, and so on. In some embodiments, the modulating comprises injecting current into the first VCSEL. The injecting current can enable degree of freedom modulation based on wavelength of light. The injecting current can affect the wavelength emitted by the first VCSEL by changing a density of carriers within the active area. In embodiments, the modulating is based on VCSEL chirp. VCSEL chirp can be a change in emission wavelength of a VCSEL due to injecting current, changing current, varying current, etc.

The flow 100 includes emitting a degree of freedom modulated beam (DFMB) 140. Modulation such as described above can be used to encode optical data. Noted above, the modulating causes the first VCSEL to emit a light beam. A DFMB can result from modulating a plane of polarization of the light, a mode of the light, a wavelength of the light, an intensity of light, etc. as described above. The DFMB can comprise an optical signal whose degree of freedom changes over time, thus encoding optical information. The degree of freedom of the beam can be sensed, allowing for the decoding of the information that is sent. Recall that electrical data is sent by a first circuit to a first VCSEL. The electrical data can be used to modulate a degree of freedom of the first VCSEL by disclosed techniques, resulting in a DFMB sent from the first VCSEL. Thus, in the flow 100, the DFMB is based on the electrical data that was sent 142.

The flow 100 includes coupling optically 150. Embodiments include coupling optically the DFMB to a waveguide with the plurality of waveguides, wherein the waveguide is further coupled to an optical decoding element. The waveguide can include a waveguide within a wafer, an interposer, and so on. Other optical mediums can be used. An optical medium can be any material, space, etc. that allows an optical signal, such as a DFMB, to propagate. The DFMB can be coupled optically to other optical media such as an optical fiber. In a usage example, the optical medium comprises a degree of freedom maintaining fiber. The degree of freedom can include a polarization of light, a light mode, a light wavelength, etc. The degree of freedom maintaining fiber can maintain fidelity of the DFMB. The first circuit and the first VCSEL can be bonded to a photonic wafer-scale interposer (PWSI) which includes a plurality of waveguides to carry optical signals from one or more VCSELs. The optical medium can comprise a waveguide within the plurality of waveguides. Recall that the first VCSEL can emit optical signals, such as the DFMB, in a vertical direction. The vertical direction can be down, toward the substrate (and the PWSI to which a VCSEL can be bonded). A waveguide within the PWSI can be oriented horizontally or substantially horizontally. Thus, the PBM can be coupled to the waveguide in order for it to propagate along a waveguide within the PWSI to another circuit bonded to the PWSI, such as a second chiplet.

In embodiments, the coupling optically is based on a grating coupler. The grating coupler can diffract light at specific frequencies, ranges of frequencies, input angles, ranges of input angles, etc. thereby providing efficient transfer of light at a specific frequency and/or frequencies into or out of a waveguide. To aid the coupling to a grating coupler, the DFMB emitted from the first VCSEL can be angled 152. Embodiments include angling the PMB that was emitted by the first VCSEL, wherein the angling is based on a micro-optical element (MOE). The MOE can be based on one or more optical techniques. For example, the MOE can comprise a micro lens. The micro lens can be coupled to the first surface-emitting light source such as a VCSEL, a laser diode, and so on. The micro lens can pre-angle the emitted light. The MOE can comprise a diffractive optical element. The diffractive optical element can create a light phase profile that can focus, shape, or split the emitted light. The MOE can include a Fresnel lens. The Fresnel lens can use concentric grooves or rings to focus the emitted light. The MOE can include an asymmetric non-focusing optical device. The asymmetric non-focusing optical device can enable light to transmit through the device preferentially, where the light can pass through more easily in one direction than another direction. The asymmetric non-focusing optical device can couple light to a waveguide and can suppress a portion of reflected light back to the surface-emitting light source. Any number and/or types of MOEs can be used in conjunction with any number of VCSELS.

Other methods of coupling the DFMB to the waveguide, or another optical medium such as an optical fiber, can be implemented. In embodiments, the coupling optically is accomplished by a mirror. The mirror can include a mirror within a circuit, a chip, a wafer, an interposer, and so on. In a usage example, the coupling is based on a crystallographic etched mirror. The crystallographic etched mirror can comprise a tetramethylammonium hydroxide (TMAH) etched mirror. The TMAH mirror can reflect incoming light at substantially a 54.74 degree angle to the waveguide. Other angles are possible with various crystallographic etched mirrors. A crystallographic etched mirror can operate in combination with a MOE, such as described above, which can be placed over or near an aperture of the first VCSEL. For example, the MOE can pre-angle light from the first VCSEL so that when the light is reflected by the TMAH mirror, it is efficiently coupled directly into the waveguide at 90 degrees, or sufficiently close to 90 degrees, from the light source. In other embodiments, the coupling optically is based on a bent waveguide. The bent waveguide can include a high containment region of a waveguide. The high containment waveguide can redirect the light while minimizing loss of light in the region of the bend of the waveguide. In embodiments, the coupling optically is based on an off-axis diffractive lens. An off-axis diffractive lens can direct light at an angle with respect to the optical axis of the lens. An off-axis diffractive lens can direct the DVMB at an angle substantially normal to an input aperture of the waveguide into the waveguide.

In the flow 100, the waveguide is further coupled to an optical decoding element (ODE) 160. An ODE can be an optical element that interprets a degree of freedom state of an optical signal. The ODE can be used to decode the DFMB at the far end of the waveguide. The flow 100 includes decoding, by the optical decoding element, the DFMB into the electrical data 170. In a usage example, the FDMB is decoded, by the ODE, into the electrical data that was sent by the first circuit. The ODE can be based on a variety of optical techniques. In some embodiments, the optical decoding element comprises a grating coupler. The grating coupler can separate different polarizations, wavelengths, modes, etc. from each other. In a usage example, the separated polarizations of light can be sent to optical receivers, where the optical receivers can convert the optical data to electrical data. In other embodiments, the optical decoding element comprises a polarization filter. A polarization filter can enable passage of light with a polarization that is compatible with the polarization filter while substantially blocking light with polarizations that are incompatible with the polarization filter. In a usage example, a first polarization filter passes light polarized with a first polarization, and a second polarization filter passes light polarized with a second polarization. In some embodiments, the optical decoding element comprises a polarization multiplexor (PMUX). The PMUX can receive light that includes two or more polarizations. The received light can be separated into two or more beams, where each beam is based on a single polarization (explained in further detail below). The decoding can be based on time-division demultiplexing (TDDM). The TDDM can reassemble two or more signals that were time-multiplexed before sending through the waveguide, optical fiber, etc.

The flow 100 includes delivering electrical data 180. Embodiments include delivering the electrical data to a second circuit within the plurality of circuits. The second circuit can comprise a chiplet. As the case with the first circuit, the second circuit can be a circuit within a chip, a core, a chiplet, an SoC, a wafer, an interposer, etc. The second circuit can comprise a processor, a chiplet, a multi-core processor, a memory controller, a memory chip such as DDR or HBM, an I/O chip, an AI accelerator, a switching chip, and so on. The second circuit can further comprise a core, a core on (or manufactured within) a wafer, etc. The second circuit and the first circuit can be on the same or different circuit boards, interposers, wafers, etc. The electrical data can be delivered to the second circuit using a variety of techniques. The delivery techniques can be based on using wire, interconnect, metal layers, and so on. The metal layers can include metal layers within a circuit board, a wafer, an interposer, and so on. The interposer can include a photonic wafer-scale interposer. The metal layers, which enable interconnection between and among circuits, chiplets, and other elements, can be fabricated on or within a circuit board, wafer, or interposer. As was the case for sending the data from the first circuit to the VCSEL, using the metal layers can offer significant inter-chiplet communications speed due to short wire lengths, and reduced “parasitics” such as resistance, capacitance, and inductance. The second circuit can process the delivered data, forward the delivered data, etc.

Various steps in the flow 100 may be changed in order, repeated, omitted, or the like without departing from the disclosed concepts. Various embodiments of the flow 100, or portions thereof, can be included in an apparatus for transmitting data or system that is configured to transmit data.

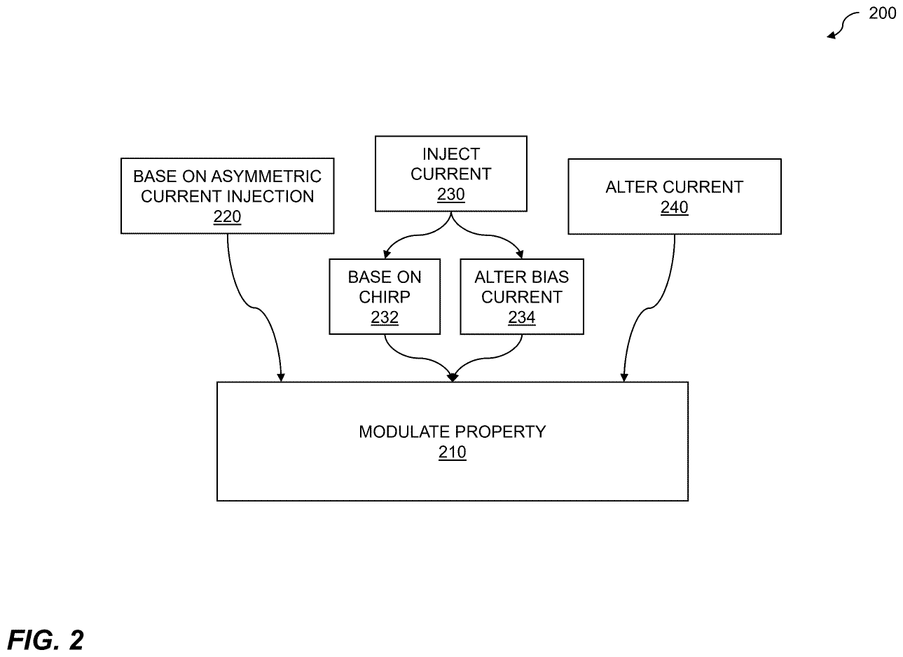

FIG. 2 is a flow diagram for degree of freedom modulation. Data is transmitted between a first circuit and a second circuit. The transmitting data is accomplished by sending the data from a first circuit to a first vertical-cavity surface-emitting laser (VCSEL). The first circuit and the first VCSEL can be bonded to a front side of a photonic wafer-scale interposer (PWSI). The first VCSEL, which can be referred to simply as a VCSEL, emits light that is based on the sent data. The light that is emitted by the VCSEL is a degree of freedom modulated beam (DFMB). The modulating can be based on asymmetric current injection, other current injection, altering current, and so on. The DFMB is coupled optically to an optical medium which transmits the data to an optical decoding element (ODE). The optical medium comprises a waveguide. The optical medium can further comprise an optical fiber. The ODE decodes the DFMB into the electrical data. The decoding can be accomplished by separating the degree of freedom modulated beam. The electrical data that was decoded is delivered to a second circuit. The separating a degree of freedom modulated beam enables optical links with degree of freedom VCSEL modulation on a photonic wafer-scale interposer.

The flow 200 includes modulating 210 a property of light. Embodiments include modulating a degree of freedom (DoF) of a light beam emitted by the first VCSEL, wherein the emitted light beam comprises a degree of freedom modulated beam (DFMB), wherein the DFMB is based on the electrical data that was sent. The modulating the light can be based on more than one degree of freedom. In embodiments, the degree of freedom comprises a polarization of the first VCSEL. The polarization can include an s-polarization and a p-polarization. An s-polarization includes polarization that is normal or perpendicular to a surface of incidence, and a p-polarization includes polarization that is parallel to a surface of incidence. The DFMB can include a mode. A mode can include a fundamental mode, a low-order mode, a high-order mode, and so on. A mode can include a transverse electromagnetic (TEM) mode. In a usage example, the TEM modes can include TEM₀₀, TEM₁₀, and TEM₀₁. The DFMB can include a wavelength. The wavelength can be based on a VCSEL chirp.

The various degrees of freedom that can modulate the light beam emitted by the VCSEL can be accomplished using a variety of techniques, where the techniques can depend on a type of modulation included within the degrees of freedom. In embodiments, the degree of freedom comprises a polarization of the first VCSEL. In embodiments, the modulating is based on asymmetric current injection 220. The politization can be controlled by asymmetric current injection. Asymmetric current injection can include sending current into an active region of the first VCSEL in a non-uniform way. The non-uniformity can influence the first VCSEL to produce polarized light in a first direction. The applied current can be altered to produce polarized light in a second direction. For example, more current can be sent to the x-axis of an active region of the first VCSEL to produce a polarization in the X plane. The current can be switched to favor the y-axis of the active region of the first VCSEL to produce a polarization in the Y plane. Modulation such as described above can be used to encode optical data. The asymmetric current injection can be based on contacts coupled to an active region of the first VCSEL. The contacts can include one or more p-contacts and one or more n-contacts. The asymmetric current injection can include a current with a DC offset, a current that includes an asymmetric wave, and the like. The asymmetric current can be based on the data that was sent by the first circuit. The DFMB can include one or more polarizations of light. When more than one polarization of light is present within the DFMB, the polarizations of light can be separated from each other. The separating polarization of light can be accomplished using an optical decoding element (ODE). The ODE can include a grating coupler, a polarization filter, a polarization multiplexor (PMUX), and so on. The PMUX can comprise various elements to decode a DFMB sent from a polarization-modulated VCSEL through an optical medium such as a waveguide, an optical fiber, etc.

The optical decoding element (ODE) can accomplish the decoding using a polarized beam splitter (PBS). The DFMB can be split into at least two polarized optical signals, where the separating can be based on a plane of polarization of the DFMB. A polarized beam splitter can substantially pass light with a polarization that is compatible with the polarization of the beam splitter and can substantially block light that is incompatible with the polarization of the beam splitter. The PBS can separate the beam based on reflection and transmission of the incoming polarized light. The reflected path and the transmitted path can comprise at least two optical signals. In a usage example, the PBS can direct x-polarized light, which can be called light polarized at 0 degrees, to a transmitted path and direct y-polarized light, which can be called light polarized at 90 degrees, to a reflected path. Other modes of polarization can be used. In another usage example, the polarized beam splitter can pass light that is polarized with an s-polarization and can reflect light that is polarized with a p-polarization. Recall that an s-polarization includes polarization that is normal or perpendicular to a surface of incidence, and a p-polarization includes polarization that is parallel to a surface of incidence. Additional states of polarization can be used in modulation such that the PBS can split the PMB into more than 2 optical signals. The PBS can be a separate optical element or can be incorporated into another optical element.

In embodiments, the degree of freedom comprises a wavelength of the first VCSEL. In some embodiments, the modulating comprises injecting current 230 into the first VCSEL. The injecting current can enable degree of freedom modulation based on wavelength of light. The injecting current can be accomplished using one or more p-contacts and one or more n-contacts, where the one or more p-contacts and the one or more n-contacts are coupled to the active region of the first VCSEL. The injecting current can affect the wavelength emitted by the first VCSEL by changing a density of carriers within the active area. In embodiments, the modulating is based on VCSEL chirp 232. A “chip”, which is a temporal change, can cause a change in wavelength of light emitted by a VCSEL. In a usage example, a VCSEL chirp can include a 1 nm to 2 nm change in emitted wavelength. The chirp can be dependent on a variety of VCSEL parameters including dynamic behavior of carrier density in a VCSEL active region; differential gain, etc. The chirp can include a positive change in wavelength or a negative change in wavelength. In some embodiments, the injecting includes altering a bias current 234 to the first VCSEL. The altering the bias current can cause a change in the wavelength of the light emitted by the first VCSEL by altering a density of carriers within the first VCSEL. The change in carrier density can change a refractive index of the first VCSEL, and thus the resonance wavelength of the first VCSEL. In a second usage example, a higher carrier density reduce the refractive index, thereby shifting the emitted light wavelength toward blue wavelengths. The electrical current can be applied to contacts such as described above.

In some embodiments, the degree of freedom comprises a mode of the first VCSEL. In embodiments, the modulating comprises altering current 240 to the first VCSEL. The altering current can enable degrees of freedom based on modes. The modes can include transverse electromagnetic (TEM) modes. The TEM modes can include a fundamental mode, a low order mode, a high order mode, and so on. In embodiments, a fundamental mode of the first VCSEL comprises a higher order mode than a non-fundamental mode. The altering current can include reversing current direction, varying current magnitude, and so on. In a usage example, the altering current can be based on current injection. Various altered currents can change the mode of the light emitted by the VCSEL. In embodiments, the first VCSEL comprises an inverted aperture VCSEL. An inverted aperture VCSEL can include a VCSEL in which the aperture from which the light is emitted is fabricated using an inverted relief technique. The inverted aperture VCSEL can also be created using an inverted p-n junction configuration. The inverted aperture VCSEL can achieve improved mode control characteristics. The inverted aperture VCSEL can be used to modulate a mode of the first VCSEL such as described above and can be used to encode optical data. In embodiments, the first VCSEL comprises a multimodal VCSEL. The modes that can be included in the multimodal VCSEL can include fundamental modes, lower order modes, high order modes, and so on. In a usage example, the supported modes can include a fundamental mode such as TEM₀₀. The multimodal VCSEL can support one or more high order transverse modes. In a usage example, the one or more high order transverse modes can include TEM₁₀, or TEM₀₁. Other TEM modes can also be used. The emitted light from the multimodal VCSEL can switch modes based on the altered current.

The degree of freedom can comprise other characteristics of the light beam. For example, adjusting the current applied to an active region of the first VCSEL can turn light emission on and off. When the current is below a threshold, lasing action can be stopped. When current levels return to a level exceeding the threshold, lasing can restart. As current is increased, a brightness, or optical power, of the first VCSEL can be increased. The altering the current can include injecting or not injecting current; changing a DC value of current; changing an AC frequency and magnitude of a current, and so on.

Various steps in the flow 200 may be changed in order, repeated, omitted, or the like without departing from the disclosed concepts. Various embodiments of the flow 200, or portions thereof, can be included in an apparatus for transmitting data or system that is configured to transmit data.

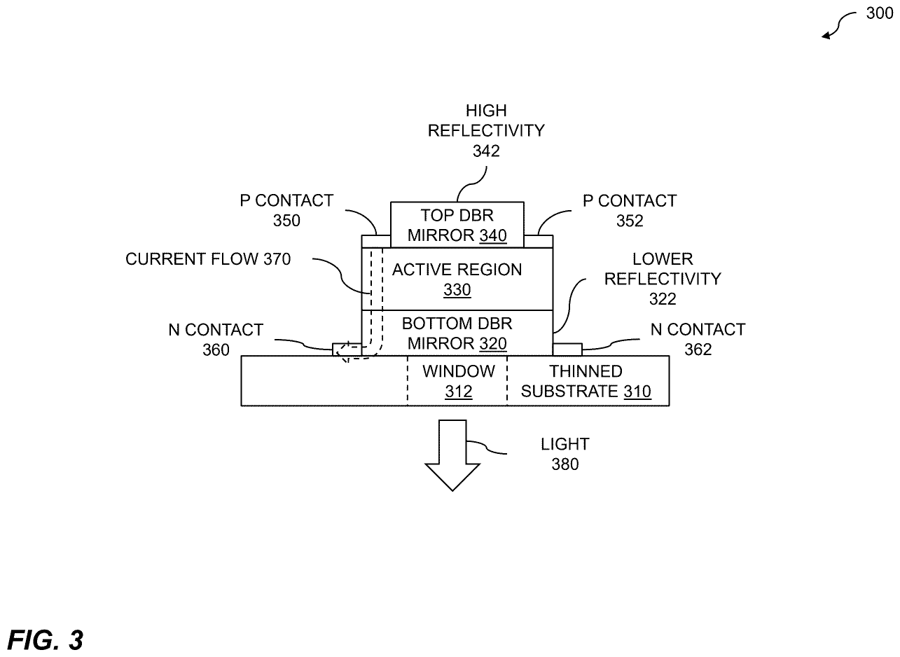

FIG. 3 is a cross-section of a VCSEL. A VCSEL enables optical links with degree of freedom modulation on a photonic wafer-scale interposer. A circuits and vertical-cavity surface-emitting lasers (VCSELs) are bonded to a front side of a photonic wafer-scale interposer (PWSI). The PWSI further includes waveguides for sending data. A first circuit, which can be a first chiplet, sends electrical data. The electrical data is sent to a first VCSEL. A degree of freedom (DoF) of the first VCSEL is modulated. The modulation causes the first VCSEL to emit a degree of freedom modulated beam (DFMB). The DFMB is based on the electrical data that was sent by the first circuit. The DFMB is coupled optically to a waveguide. The coupling optically can be accomplished using a grating coupler, a mirror, and so on. The waveguide is further coupled to an optical decoding element (ODE). The ODE decodes the DFMB into the electrical data. The electrical data that was decoded is delivered to a second circuit, which can be a second chiplet.

The block diagram 300 includes a thinned substrate 310. The thinned substrate can include a variety of materials suitable to fabricating a VCSEL. In a usage example, the substrate can include a gallium-arsenide (GaAs) substrate. Other materials that can be used for the substrate can include aluminum-gallium-arsenide (AlGaAs), germanium (Ge), sapphire, and so on. The substrate can be thinned to enable fabrication of an aperture or window 312. The thinning of the substrate can be accomplished by grinding, polishing, etching, and so on. Light in the form of a polarization-modulated beam (PMB) is emitted by the VCSEL. The light emitted by the VCSEL can exit the VCSEL by passing through the window in the thinned substrate.

The VCSEL structure comprises of an active region that is placed between two highly reflective mirrors. The first mirror includes a first reflectivity, and the second mirror includes a second reflectivity. In a usage example, the two highly reflective mirrors can be based on Distributed Bragg Reflectors (BDRs). These mirrors can be formed from multiple, alternating layers of materials, where the materials have different refractive indices. In the block diagram 300, a Distributed Bragg Reflector mirror can include a bottom mirror 320. The bottom mirror can include an n-Distributed Bragg Reflector. The bottom mirror can include a reflectivity that is lower than a top mirror (described below). In a usage example, the reflectivity 322 of the bottom DBR can include a reflectivity of 93 percent to 99 percent, or another suitable reflectivity. The n-Distributed Bragg Reflectors associated with the bottom mirror can be insulated from other layers in the block diagram by an oxide layer (not shown).

The block diagram 300 includes an active region 330. The active region can comprise a region in which light that is emitted by the VCSEL can be generated. The light can be generated using a variety of techniques. In a usage example, the active region can include a structure such as a quantum well structure. The active region can be located within a laser cavity. The block diagram 300 can include an additional oxide layer (not shown) between the active region and a top DBR mirror. The oxide layer between the bottom mirror and the active area, and the oxide layer between the active layer and the top mirror may or may not be present in the VCSEL. When present, the oxide layers can confine the light and electrical current within the active area. The block diagram 300 includes p-Distributed Bragg Reflector mirror 340. In the block diagram 300, the p-Distributed Bragg Reflector mirror comprises the top mirror of the VCSEL. The top mirror can include a high reflectivity 342. In a usage example, the reflectivity of the top DBR can include a reflectivity of 99.4 percent to 99.9 percent. Other suitable reflectivities can be implemented.

An electrical current is applied to the VCSEL in order for the VCSEL to lase in order to emit coherent light. The applied electrical current can include a DC current, a pulsed current, and so on. The current can include a symmetrical current, an asymmetrical current, etc. The applied current can modulate the light emitted by the VCSEL. In embodiments, modulating is based on asymmetric current injection. An injected asymmetrical current can include a current that is unbalanced or unequal with respect to distribution and/or direction. In a usage example, the current is asymmetrical about the x-axis, that is, the asymmetrical current has a DC offset. The injection of the asymmetrical current can cause the modulated light emitted by the VCSEL to include a polarization. Changing the injected asymmetrical current can change the polarization of the emitted light. The electrical current can be applied to the top p-contact. The p-contact can include a single contact, a ring contact, a “broken ring” contact where the ring is broken into two or more segments, and so on. In the block diagram 300, the contact includes one or more p-contacts such as p-contact 350 and p-contact 352.

In embodiments, the VCSEL includes a ferroelectric liquid crystal layer (FLC). The FLC can include liquid crystals that can be oriented by an electric field. Applying a voltage to the FLC can influence the polarization (e.g., a degree of freedom) of light emitted by the VCSEL. In a usage example, a VCSEL with an FLC can include a bottom DBR, a middle DBR with the FLC layer on top of the middle layer. A top DBR can be included on top of the FLC layer. Other VCSEL layouts, topologies, etc. are possible.

The electrical current can exit the bottom of the VCSEL via one or more n-contacts. The n-contacts can include a single contact, a ring contact, a broken ring contact, etc. In the block diagram 300, the one or more n-contacts include n-contact 360 and n-contact 362. In a usage example, a p-contact ring and an n-contact ring can be concentric broken rings. By accessing a portion of the p-contact ring and the opposite (e.g., diagonally opposite) n-contact ring a first polarization can be achieved. By accessing the previously unused portion of the p-contact and the previously unused portion of the n-contact, a second polarization can be achieved. In these cases, the electrical current flows 370 from a first p-contact to a second n-contact (e.g., diagonal opposites), from a second p-contact to a first n-contact, and so on. The VCSEL emits light 380. The light from the VCSEL can be emitted at an angle that can be substantially normal to a substrate, chip, PCB, interposer, etc. to which the VCSEL can be coupled. When there is a purpose for the light emitted by the VCSEL to be angled, then an optical device can be used. The purpose for angling the light can include enhancing optical coupling of the polarization-modulated beam (PMB). Embodiments include angling the PMB that was emitted by the VCSEL, wherein the angling is based on a micro-optical element (MOE). The MOE can include a micro lens, a diffractive optical element, a Fresnel lens, an asymmetric non-focusing optical device, and so on.

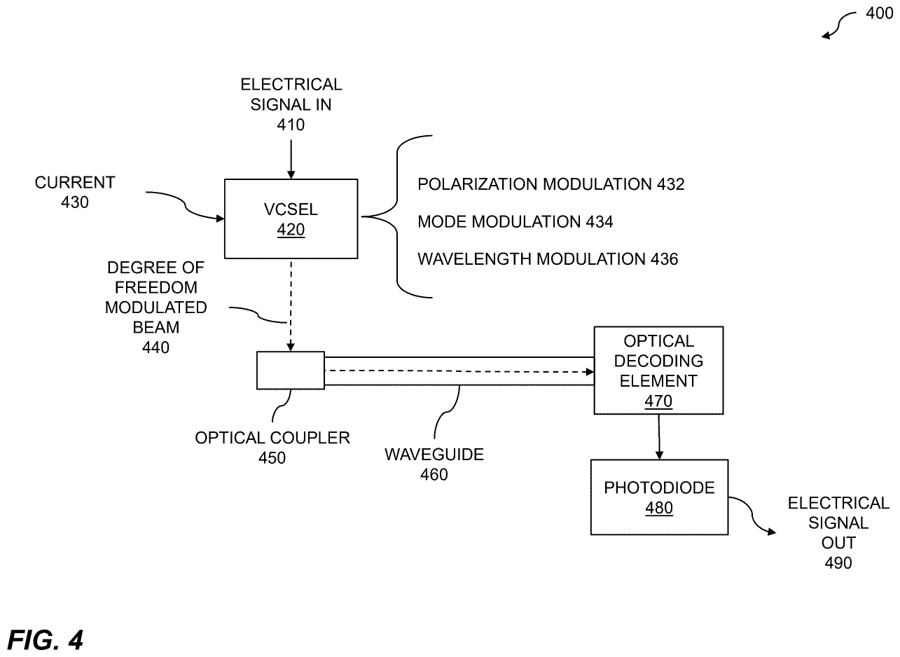

FIG. 4 is a block diagram of an optical link with degree of freedom VCSEL modulation. An optical link with VCSEL degree of freedom modulation enables transmitting data between a first circuit and a second circuit. One or more circuits and vertical-cavity surface-emitting lasers (VCSELs) are bonded to a front side of a photonic wafer-scale interposer (PWSI). The PWSI also includes waveguides. A first circuit, which can be a first chiplet, sends electrical data. The electrical data is sent to a first VCSEL. The first VCSEL is modulated. The modulation causes the first VCSEL to emit a degree of freedom modulated beam (DFMB). The DFMB is based on the electrical data that was sent. The DFMB is coupled optically to a waveguide. The coupling optically can be accomplished using a grating coupler, a mirror, and so on. The waveguide is further coupled to an optical decoding element (ODE). The ODE decodes the DFMB into the electrical data. The electrical data that was decoded is delivered to a second circuit, which can be a second chiplet.

The block diagram 400 includes an electrical signal in 410. The electrical signal can represent data such as image data, video data, and audio data; artificial intelligence (AI) weights, biases, and data; natural language data; and so on. The electrical signal can represent parallel data such as a data set as bytes, words, double words, etc. The electrical data can represent serial data.

The block diagram includes a vertical-cavity surface-emitting laser (VCSEL) 420. A VCSEL can be a semiconductor laser fabricated on a chip. The VCSEL can comprise a VCSEL array. The VCSEL array can include a plurality of VCSELs. The fabrication can be based on gallium arsenide or another suitable material. The VCSEL can emit light in a direction perpendicular to the chip. The direction can be up (e.g., away from the chip) or down (e.g., into the chip). When light is emitted down, a window can be provided so that the light can escape through the back of the chip. To aid projection of the light, the substrate of the chip can be thinned. The light that is emitted can be coherent light that is in a wavelength range, such as 850 nm-950 nm. Other ranges are possible.

The block diagram 400 includes changing current 430 to the VCSEL, which can be a first VCSEL such as described above. The current can comprise the basis for modulating a degree of freedom, such as phase, mode, or wavelength, of light emitted from the first VCSEL. In embodiments, the degree of freedom comprises a polarization of the first VCSEL 432. In embodiments, the modulating is based on asymmetric current injection. The asymmetric current injection can affect the polarization of the light emitted by the VCSEL. In a usage example, the light emitted by the VCSEL can include an s-polarization, which includes polarization that is normal or perpendicular to a surface of incidence, or a p-polarization, which includes polarization that is parallel to a surface of incidence.

In some embodiments, the degree of freedom comprises a mode of the first VCSEL 434. In embodiments, the modulating comprises altering current to the first VCSEL. As described previously, a mode can include a transverse electromagnetic (TEM) mode. In a usage example, the TEM modes can include TEM₀₀, TEM₁₀, and TEM₀₁. The TEM₀₀ mode can include a fundamental mode, while the TEM₁₀ mode and the TEM₀₁ mode can include higher order modes. The altering current can change the transverse electromagnetic (TEM) mode of the VCSEL.

In other embodiments, the degree of freedom comprises a wavelength of the first VCSEL 436. In embodiments the modulating comprise injecting current into the first VCSEL. In embodiments, the injecting includes altering a bias current to the VCSEL. The altering the bias current can change current density within the active area of the VCSEL. The altering current density can change a refractive index of the VCSEL and thereby change the resonance wavelength of the VCSEL. The wavelength can be changed by VCSEL chirp.

The block diagram 400 includes a degree of freedom modulated beam 440. Recall that data is sent from a first circuit to a VCSEL. Embodiments include modulating a degree of freedom (DoF) of a light beam emitted by the first VCSEL, wherein the emitted light beam comprises a degree of freedom modulated beam (DFMB), wherein the DFMB is based on the electrical data that was sent. The DFMB can be directed through a VCSEL window or aperture toward an optical coupler 450. The optical coupler can include a coupler on or within a circuit board, a wafer, an interposer, etc. The optical coupler can be based on a variety of optical elements, techniques, and so on. In embodiments, the coupling optically is based on a grating coupler. The grating coupler can include a periodic grating that can transfer the DFMB with low loss into the waveguide. In other embodiments, the coupling optically is based on a mirror. In a usage example, the mirror can include a nano-imprint lithography mirror. In embodiments, the coupling optically is based on a bent waveguide. The bent waveguide can include a maximum containment region to minimize light loss. In further embodiments, the coupling optically is based on an off-axis diffractive lens. An off-axis diffractive lens can direct light at an angle with respect to the optical axis of the lens. Embodiments include angling the DFMB that was emitted by the first VCSEL, wherein the angling is based on a micro-optical element (MOE) (not shown). The angling the PMB can be used to complement an angle associated with the coupling the WMB to the optical medium.

The block diagram includes a waveguide 460. The waveguide can comprise an optical medium that is capable of transferring the DFMB coupled to the waveguide by the optical coupler. Embodiments include coupling optically the DFMB to a waveguide with the plurality of waveguides, wherein the waveguide is further coupled to an optical decoding element. The waveguide can include a waveguide on or within a wafer, an interposer, and so on. In a usage example, the waveguide can be replaced by a fiber. The block diagram 400 includes an optical decoding element (ODE) 470 to which the waveguide is further coupled. The ODE can be based on a variety of optical elements, optical techniques, and so on. Embodiments include decoding, by the optical decoding element, the DFMB into the electrical data. The ODE can separate different degrees of freedom of light from the DFMB. The separated degrees of freedom of light (e.g., optical data) can be decoded into electrical data that was sent by the first circuit. The ODE can accomplish decoding the DFMB based on a variety of decoding techniques. In embodiments, the optical decoding element comprises a grating coupler. The grating coupler can separate different degrees of freedom of light from each other. In a usage example, the separated degrees of freedom of light can be sent to optical receivers, where the optical receivers can convert the optical data to electrical data. In another usage example, the grating coupler can indicate when a first degree of freedom is active in the optical medium, which can comprise a logic “1”. The absence of the signal from the grating coupler can comprise a logic “0”. Clocking, such as clock and data recovery (CDR) circuits can synchronize the WMB with the receiving and/or decoding circuits. In other embodiments, the optical decoding element comprises a polarization filter. The polarization filter can enable a first polarization of light to pass through the polarization filter while a second polarization of light is reflected by the polarization filter. In further embodiments, the optical decoding element comprises a polarization multiplexor (PMUX). The multiplexer can combine different polarizations when the DFMB is coupled optically to the waveguide, and the multiplexer can separate the different polarizations of the DFMB at the far end of the waveguide.

Some block diagram examples can include transforming each optical signal within at least two optical degree of freedom signals, by a unique photodiode, to an electrical signal. The transforming would then result in at least two electrical signals. The block diagram 400 includes a photodiode 480. More than one photodiode can be included, where each photo diode can transform or decode an optical signal into an electrical signal. In the block diagram 400, the ODE decodes the DFMB into the electrical data that was sent. The decoded DFMB is sent as an electrical signal out 490. Discussed previously, each optical signal within at least two optical degree of freedom signals is transformed by a unique photodiode to an electrical signal. The transforming results in at least two electrical signals. The at least two electrical signals can be assembled into a single electrical signal, where the single electrical signal comprises the electrical data that was sent. Embodiments include delivering the electrical data that was decoded to a second circuit within the plurality of circuits. The single electrical signal that includes the electrical data that was sent can be sent to a destination element such as a second circuit. The destination element can include a processor, an AI accelerator chiplet, a switching chiplet, etc. In embodiments, the first circuit and the second circuit comprise a first chiplet and a second chiplet, respectively.

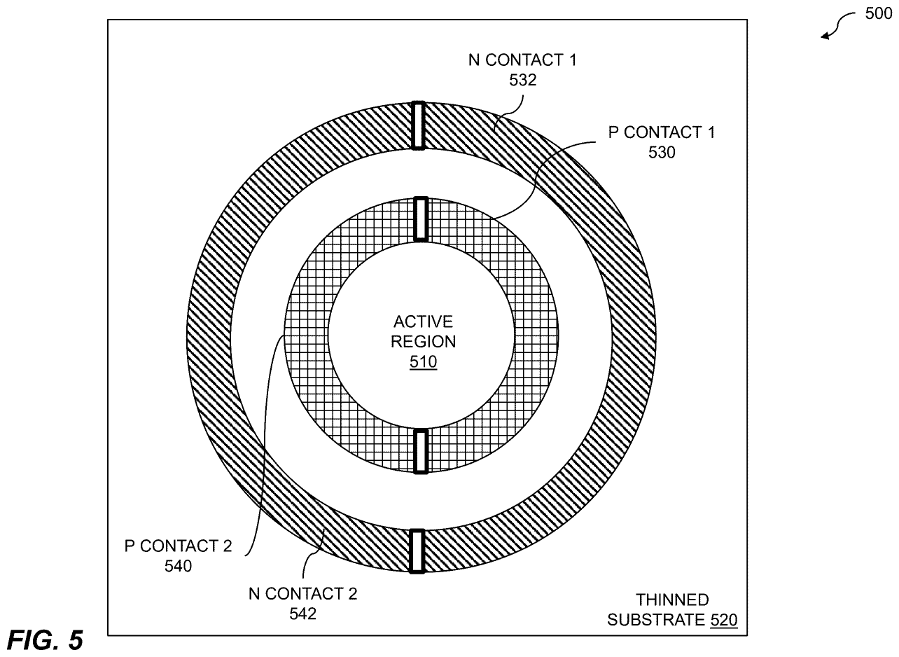

FIG. 5 is a diagram for asymmetric current injection for polarization modulation. The asymmetric current injection can be accomplished using contacts associated with a VCSEL. Described previously, a degree of freedom of light emitted by a VCSEL comprises modulating a polarization the VCSEL. A first circuit sends electrical data. The electrical data is sent to a first vertical-cavity surface-emitting laser (VCSEL). A polarization of the first VCSEL is modulated. The modulating can be based on asymmetric current injection. An injected asymmetrical current is a current that is unbalanced or unequal with respect to distribution and/or direction. The distribution and/or direction of the current can include a duration during which the current is positive, the current is negative, and so on. In a usage example, a current is asymmetrical about the x-axis, resulting in the asymmetrical current having a DC (e.g., nonzero) offset. The injection of the asymmetrical current can cause the first VCSEL to emit modulated light that includes a polarization. Thus, changing the injected asymmetrical current can change the polarization of the modulated, emitted light. The changing the injection of the asymmetrical current can be accomplished using contacts associated with the first VCSEL. The contacts can include n-contacts and p-contacts, where the n-contacts are based on an n-type diffusion or implantation, and the p-contacts are based on a p-type diffusion or implantation. The n-contacts and the p-contacts enable optical links with degree of freedom VCSEL modulation on a photonic wafer-scale interposer (PWSI). The modulation causes the first VCSEL to emit a degree of freedom modulated beam (DFMB), where the DFMB comprises a polarization-modulated beam (PMB). The DFMB is based on the data that was sent by the first circuit. The DFMB is coupled optically to a waveguide. The coupling optically can be accomplished using a grating coupler, a mirror, and the like. The waveguide is further coupled to an optical decoding element (ODE). The ODE decodes the DFMB into the electrical data. The electrical data that was decoded is delivered to a second circuit. In embodiments, the first circuit and the second circuit comprise a first chiplet and a second chiplet, respectively.

The figure 500 shows an active region 510 of the VCSEL, which can be a first VCSEL such as described above. Light to be emitted by the VCSEL is generated within the active region. The active region can include a structure such as a quantum well structure. A top view of the VCSEL shows a thinned substrate 520. The thinned substrate can comprise a variety of materials suitable to fabricating a VCSEL such as a gallium-arsenide (GaAs) substrate. Other materials that can be used for the substrate can include aluminum-gallium-arsenide (AlGaAs), germanium (Ge), sapphire, and so on. The substrate can be thinned using a variety of fabrication techniques. The thinning the substrate can be accomplished by grinding, polishing, etching, and so on. The figure 500 shows p-contacts and n-contacts associated with a VCSEL. The contacts can be configured based on various geometries such as rings, squares, and so on. The contacts can be based on a variety of contacts. In the figure, a p-contact comprises two segments, p-contact 1 530 and p-contact 2 540. The p-contact can include any number of segments. Also, in the figure, the n-contact comprises two segments, n-contact 1 532 and n-contact 2 542. The while two segments are shown, the n-contact can also include any number of segments.

Modulating the polarization of the light emitted by the VCSEL can be accomplished using asymmetric current injection into one or more p-contacts and one or more n-contacts. The asymmetric current can be injected using opposite pairs of p-contacts and n-contacts. In a usage example, a first pair of opposite contacts can include p-contact 1 and n-contact 2, and a second pair of opposite contacts can include p-contact 2 and n-contact 1. Different polarization-modulated beams (PMBs) can be emitted by the VCSEL depending on which p-contacts and which n-contacts are used for the current injection. Alternatively, current can be applied to the VCSEL using all of the p-contacts and all of the n-contacts, a portion of the p-contacts and a portion of the n-contacts, adjacent p-contacts and n-contacts (such as p-contact 1 and n-contact 1), and so on.

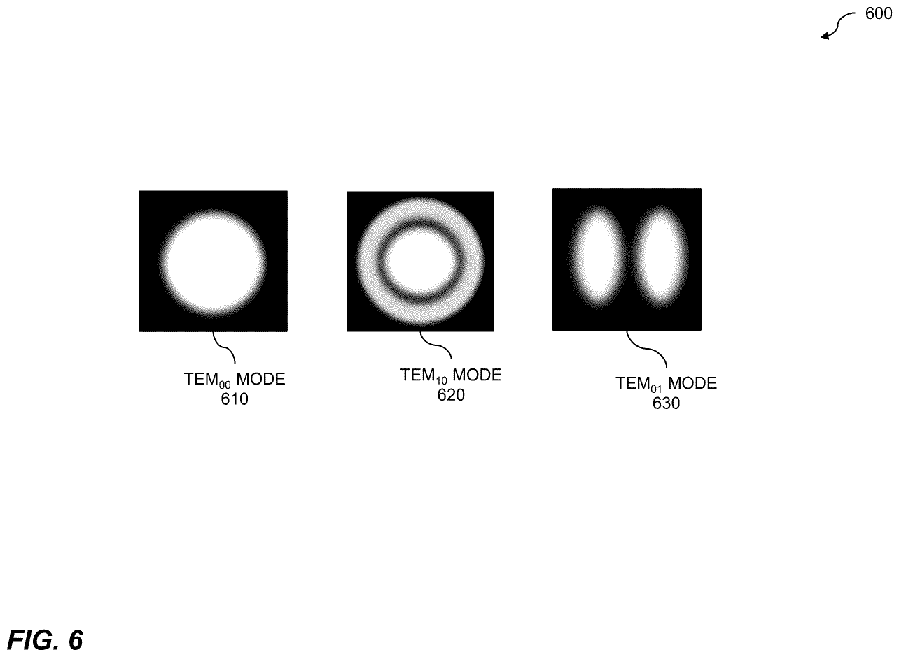

FIG. 6 is a diagram of transverse electromagnetic (TEM) modes. Described previously, the degree of freedom modulation of a VCSEL can include a mode. The mode of a VCSEL can be modulated by altering a current to the VCSEL. The mode can include a transverse electromagnetic (TEM) mode, for which electric fields and magnetic fields are perpendicular to the direction of propagation of a wave such as a light wave emitted by the VCSEL. One or more TEM modes can be used to transmit data between electronic elements such as chips, chiplets, circuits, and so on, where the electronic elements can be co-located on a circuit board, wafer, interposer, and the like. The interposer can include a photonic wafer-scale interposer (PWSI). The electronic elements can also be located on different boards, wafers, and interposers, located in different multiprocessors, located in different data racks or different datacenters, etc. The one or more transverse modes enable optical links with degree of freedom VCSEL modulation on a photonic wafer-scale interposer. An optical link that modulates VCSEL modes enables transmitting data between a first circuit and a second circuit. In embodiments, the first circuit and the second circuit comprise a first chiplet and a second chiplet, respectively. Circuits and VCSELs are bonded to a front side of a PWSI. The PWSI includes waveguides.

A first circuit sends electrical data. The electrical data is sent to a vertical-cavity surface-emitting laser (VCSEL). A degree of freedom that includes a mode of the VCSEL is modulated. The modulating can be based on altering current to the VCSEL. The modulation causes the VCSEL to emit a mode-modulated beam (MMB). The MMB is based on the electrical data that was sent. The MMB is coupled optically to a waveguide. The coupling optically can be accomplished using a grating coupler, a mirror, etc. The waveguide is further coupled to a mode-dependent optical element (MDOE). The MDOE decodes the MMB into the electrical data. The electrical data that was decoded is delivered to a second circuit.

The figure 600 shows example transverse electromagnetic (TEM) waves. The TEM waves result from modulating a mode of a VCSEL. The TEM modes, which can propagate via an optical medium such as a waveguide or an optical fiber, can transmit data between chips, chiplets, circuits, and so on. A variety of TEM modes can be modulated. In embodiments, the VCSEL comprises a multimodal VCSEL. The modulating modes of the VCSEL can be accomplished by an electric current. In embodiments, the modulating comprises altering current to the VCSEL. The altering the current can include turning on a current and turning off a current, reversing a current, applying an asymmetric current, and so on. In embodiments, the multimodal VCSEL supports one or more high order transverse modes. Thus, the modulating can be based on switching modes. In embodiments, the modulating comprises switching between a lower order transverse mode and a high order transverse mode within the one or more high order transverse modes.

A variety of TEMs can be used for transmitting data. In a usage example, a lower order or fundamental mode can include TEM₀₀ 610. TEM₀₀ comprises a Gaussian beam profile that includes a single peak in intensity at the center. One or more high order TEMs can be included in the variety of modulation modes. Two additional TEM modes can include TEM₁₀ 620 and TEM₀₁ 630. The subscripts associated with each TEM denote an order of the mode in a horizontal direction and a vertical direction, respectively. The higher order modes can include a plurality of peak intensities and a plurality of nodes (e.g., an intensity substantially equal to zero). For TEM₁₀, there are two concentric intensity peaks. For TEM₀₁, there are two vertical, parallel intensity peaks. Other TEM modes can be used. The various TEM modes can be used to represent binary values. In a usage example, a first TEM mode can represent a binary one while a second TEM mode can represent a binary zero. In another usage example, the presence of a TEM mode can represent a binary one, while the absence of a TEM mode can indicate a binary zero. In a further usage example, two different TEM modes can represent two different data streams. For the latter usage example, the TEM mode can be captured and re-clocked in order to decode electrical data such as serial electrical data that was sent by the first circuit. The decoded data can be delivered to a second circuit.

The result of modulating the VCSEL by altering current to the VCSEL is a degree of freedom modulated beam (DFMB) that comprises a mode-modulated beam (MMB), where the MMB is based on electrical data sent by a first circuit to the VCSEL. The MMB can be coupled to an optical medium such as a waveguide, a single mode fiber, and so on. The optical medium is coupled to a mode-dependent optical element (MDOE) which decodes the MMB into the electrical data that was sent. The electrical data that was decoded is delivered to a second circuit, thereby completing transmitting data from the first circuit to the second circuit.

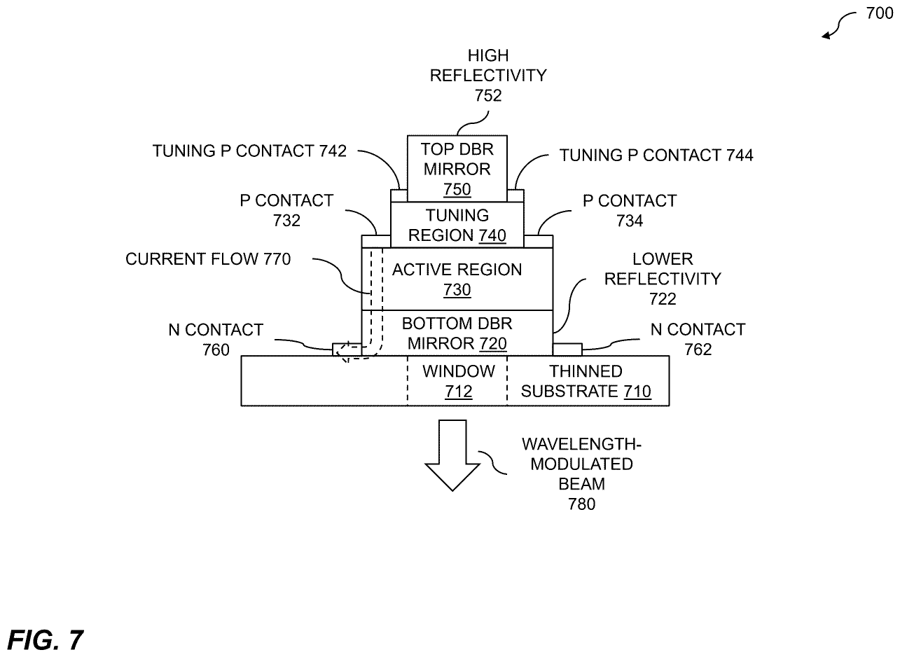

FIG. 7 is a cross-section of a VCSEL with a tuning region for wavelength modulation. The wavelength modulation is achieved by injecting current into the VCSEL. A VCSEL enables optical links with wavelength modulation. The VCSEL includes a tuning region. The tuning region enables wavelength modulation of a beam emitted by the VCSEL. A first circuit sends electrical data. The electrical data is sent to a vertical-cavity surface-emitting laser (VCSEL). A wavelength of the VCSEL is modulated. The modulating can be based on current injection, where the injecting includes altering a bias current to the VCSEL. The modulation causes the VCSEL to emit a wavelength-modulated beam (WMB). The altering bias current controls carrier densities within the VCSEL and thus wavelengths of light within the WMB. The WMB is based on the data that was sent by the first circuit. The WMB is coupled optically to a waveguide. In a usage example, the WMB can be coupled optically to an optical fiber. The coupling optically is accomplished using a grating coupler, a mirror, and so on. The waveguide is further coupled to a wavelength-dependent optical element (WDOE). The WDOE decodes the WMB into the electrical data. The electrical data that was decoded is delivered to a second circuit. The first circuit and the second circuit can comprise a first chiplet and a second chiplet, respectively.

The block diagram 700 includes a thinned substrate 710. Described previously, the thinned substrate can include a variety of materials suitable to fabricating a VCSEL, such as gallium-arsenide (GaAs) substrate, an aluminum-gallium-arsenide (AlGaAs) substrate, a germanium (Ge) substrate, a sapphire substrate, and so on. The substrate can be thinned to enable fabrication of an aperture or window 712. Light in the form of a wavelength-modulated beam (WMB) is emitted by the VCSEL through the window in the thinned substrate. The WMB can be conveyed into a circuit board, a wafer, an interposer such as a photonic wafer-scale interposer (PWSI), and the like, where the WMB can be coupled to a waveguide, an optical fiber, etc. The WMB enables transmitting data between a first circuit and a second circuit.

The VCSEL structure comprises an active region coupled between two opposing highly reflective mirrors. A first mirror includes a first reflectivity, and a second mirror includes a second reflectivity. In a usage example, the two highly reflective mirrors can be based on Distributed Bragg Reflectors (DBRs). These mirrors can be formed from multiple, alternating layers of materials, where the materials have different refractive indices. In the block diagram 700, a Distributed Bragg Reflector mirror can include a bottom mirror 720. The bottom mirror can include an n-Distributed Bragg Reflector. The bottom mirror can include a reflectivity that is lower than a top mirror (described below). In a usage example, the reflectivity 722 of the bottom DBR can include a “low” (relative to a top mirror) reflectivity of 93 percent to 99 percent, or another suitable reflectivity. The n-Distributed Bragg Reflectors associated with the bottom mirror can be insulated from other layers in the block diagram by an oxide layer (not shown). A tuning region (described below) associated with the VCSEL can be coupled between the active area and a top mirror. The tuning region can tune the active region to a wavelength within a range of wavelengths.

The block diagram 700 includes an active region 730. The active region can comprise a region in which light that is emitted by the VCSEL can be generated. The light can be generated using a variety of techniques. In a usage example, the active region can include one or more structures such as quantum well structures. In another usage example, the active region can include one or more quantum dots. The active region can be located within a laser cavity. The block diagram 700 can include an additional oxide layer (not shown) between the active region and a tuning region (when present), a top DBR mirror, and so on. The oxide layer between the bottom mirror and the active area, and oxide layer between the active layer and the top mirror may or may not be present in the VCSEL. When present, the oxide layers can confine the light and electrical current within the active area. The block diagram 700 includes a p-Distributed Bragg Reflector mirror 750. In the diagram 700, the p-Distributed Bragg Reflector mirror comprises the top mirror of the VCSEL. The top mirror can include a high reflectivity 752. In a usage example, the reflectivity of the top DBR can include a reflectivity of 99.4 percent to 99.9 percent. Other suitable values of reflectivity can be implemented.

The block diagram 700 includes a tuning region 740. The tuning region is used to tune the active area to enable the active area to generate a wavelength of light. The generated wavelength of light can be within a range of wavelengths, a light band, and so on. The tuning region can be calibrated. The calibrating can include determining one or more electrical parameters that control the optical characteristics of the VCSEL. The parameters can further include temperature characteristics. In a usage example, the calibrating can include determining one or more currents required to switch between two or more spectral modes of the VCSEL. The calibrating can produce a peak gain of the VCSEL with substantially 0 volts tuning voltage. Calibrating the VCSEL for peak gain at substantially 0 volts can enable significant operating power reduction. The calibrated turning region of the VCSEL can enable wavelength modulation of the VCSEL. The modulating can comprise changing an applied bias to the tuning region. The applied bias can include an applied current, and applied voltage, or both an applied current and an applied voltage. The applied bias can be provided to the tuning region using one or more tuning contacts. The one or more contacts can include p-contacts. The contacts can comprise a ring, a broken ring, etc. In the figure 700, the one or more p-contacts can include tuning p-contact 742 and tuning p-contact 744.

A tunable VCSEL can be based on a variety of techniques. In a usage example, the VCSEL comprises a micro-electro-mechanical-system VCSEL (MEMS VCSEL). The MEMS VCSEL can electro-mechanically adjust the length of the laser cavity within the VCSEL, thereby enabling wavelength modulation of the cavity. In another usage example, the MEMS VCSEL can comprise one or more adjustable Distributed Bragg Reflectors (DBRs). In this latter configuration, the DBR is moved based on an applied voltage, an applied temperature, and so on. Further usage examples can include altering the one or more adjustable DBRs, where the altering is based on a voltage.

Discussed previously and throughout, an electrical current is used to enable the VCSEL to lase. The lasing enables the VCSEL to emit coherent light. In embodiments, the modulating comprises injecting current into the VCSEL. The injected current can modulate the light emitted by the VCSEL. The modulating can include modulating a wavelength of the light. In embodiments, the injecting includes altering a bias current to the VCSEL. The altering the bias current can cause a change in the wavelength of the light emitted by the VCSEL. Discussed above, in a usage example, the altering the bias current can change a density of carriers within the VCSEL. The change in carrier density can change a refractive index of the VCSEL, and thus the resonance wavelength of the VCSEL. In a second usage example, a higher carrier density reduces the refractive index, thereby shifting the emitted light wavelength toward blue wavelengths. The electrical current can be applied to contacts such as one or more p-contacts.

In a usage example, the electrical current can be applied to a top p-contact. The p-contact can include a single contact, a ring contact, a “broken ring” contact where the ring is broken into two or more segments, and so on. In the figure 700, the contact to the VCSEL active area includes one or more p-contacts such as p-contact 732 and p-contact 734.

The electrical current that is injected into the VCSEL can exit the bottom of the VCSEL via one or more n-contacts. The n-contacts can include a single contact, a ring contact, a broken ring contact, etc. In the figure 700, the one or more n-contacts include n-contact 760 and n-contact 762. In a usage example, a p-contact ring and an n-contact ring can be concentric broken rings. By altering a bias current to the tuning region, and altering a bias current to the active region, a wavelength of light emitted by the VCSEL can be modulated. The electrical current flows 770 from a p-contact to an n-contact. The VCSEL emits light 780 via the VCSEL window or aperture 712. The light from the VCSEL can be emitted at an angle that can be substantially normal to a chip, a substrate, a PCB, an interposer such as a PWSI, etc. to which the VCSEL can be coupled. When there is a purpose for the light emitted by the VCSEL to be angled, then an optical device can be used. The purpose for angling the light can include enhancing optical coupling of the wavelength-modulated beam (WMB). Embodiments include angling the WMB that was emitted by the VCSEL, wherein the angling is based on a micro-optical element (MOE). The MOE can include a micro lens, a diffractive optical element, a Fresnel lens, an asymmetric non-focusing optical device, and so on.

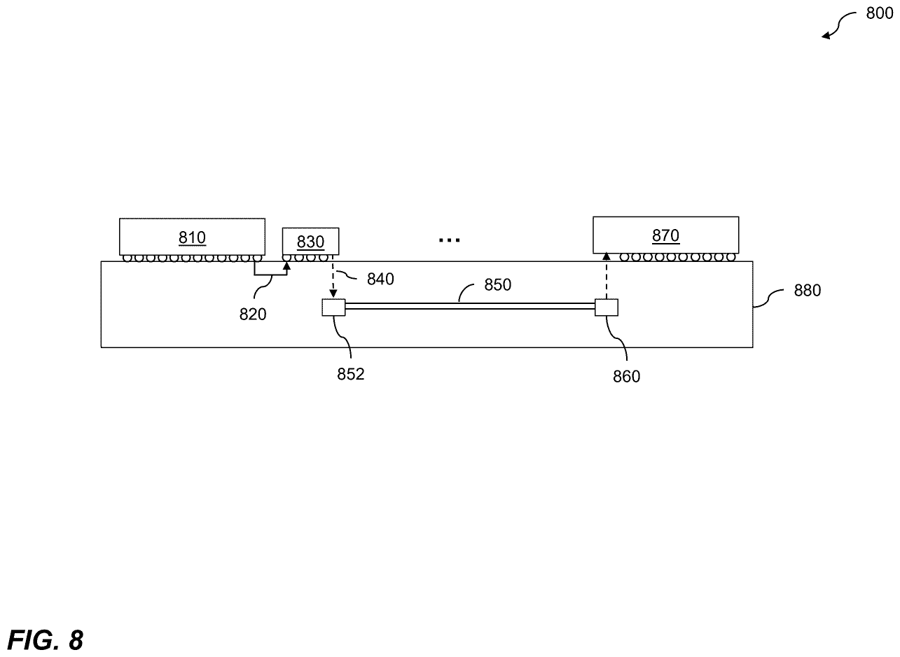

FIG. 8 is an apparatus for an optical link with degree of freedom VCSEL modulation. The degree of freedom modulation can include one or more of polarization modulation, mode modulation, wavelength modulation, and so on. Optical links that enable transmitting data can be established. The optical links can be used to send data from a first circuit to a second circuit. In embodiments, the first circuit and the second circuit comprise a first chiplet and a second chiplet, respectively. The first circuit and the second circuit can be co-located on a circuit board, wafer, or interposer; located in different multiprocessors; located in different datacenters; and so on. The interposer can include a photonic wafer-scale interposer. In embodiments, a first circuit sends electrical data to a first vertical-cavity surface-emitting laser (VCSEL). The first VCSEL converts electrical data into optical data (e.g., light data) by modulating a light beam. The first VCSEL modulation includes modulating a degree of freedom (DoF) of a light beam emitted by the first VCSEL, wherein the emitted light beam comprises a degree of freedom modulated beam (DFMB). The DFMB is based on the electrical data that was sent. By coupling the modulated beam to an optical medium such as a waveguide, a fiber, and so on, the DFMB is sent via the optical medium to an optical decoding element (ODE). The ODE decodes the DFMB to electrical data. The electrical data is delivered to the second circuit. The apparatus enables transmitting data using optical links with degree of freedom VCSEL modulation on a photonic wafer-scale interposer (PWSI).

An apparatus is disclosed for transmitting data comprising: a photonic wafer-scale interposer (PWSI), wherein the PWSI includes a plurality of waveguides, and wherein a plurality of circuits and a plurality of vertical-cavity surface-emitting lasers (VCSELs) are bonded to a front side of the PWSI; a first circuit within the plurality of circuits, wherein the first circuit is coupled to a first VCSEL within the plurality of VCSELs, wherein the first circuit sends electrical data to the first VCSEL, and wherein the first VCSEL, when modulated, emits a degree of freedom modulated beam (DFMB); an optical coupler, wherein the optical coupler couples optically the DFMB to a first waveguide within the plurality of waveguides; an optical decoding element, wherein the optical decoding element is further coupled to the first waveguide, and wherein the optical decoding element decodes the DFMB into the electrical data that was sent; and a second circuit within the plurality of circuits, wherein the second circuit receives the electrical data that was decoded.

The apparatus 800 includes a first circuit 810 within a plurality of circuits, wherein the first circuit is coupled to a first VCSEL within a plurality of VCSELs, wherein the first circuit sends electrical data to the first VCSEL, and wherein the first VCSEL, when modulated, emits a degree of freedom modulated beam (DFMB). The modulating can be based on current. The current can be injected, altered, and so on. In embodiments, the modulating is based on asymmetric current injection. The asymmetry of the current can be relative to an x-axis (e.g., include a DC offset), based on a forward current and a reverse current, related to a pulse train, etc. In a usage example, the asymmetric current injection can be used to control a polarization of the light emitted by the first VCSEL. In other embodiments, the modulating comprises altering current to the first VCSEL. The altering the current can include increasing and decreasing the current, reversing the current, applying and removing the current, etc. In a usage example, the altering the current can control a mode such as a TEM mode of light emitted by the first VCSEL. In further embodiments, the modulating comprises injecting current into the first VCSEL. The injecting the current can change carrier density with an active region of the first VCSEL. In a usage example, the injecting current can control a wavelength of light emitted by the first VCSEL.

Noted above, the first circuit sends data 820 to a second circuit 870 using the first VCSEL and additional optical elements. The circuits can be connected, attached, bonded, or otherwise coupled to a circuit board, a wafer, an interposer, and so on. In embodiments, the interposer comprises a photonic wafer-scale interposer (PWSI), wherein the PWSI includes a plurality of waveguides. While two circuits and one VCSEL are shown, the apparatus can include any number of circuits and any number of VCSELs. The circuits can include AI accelerators, switching circuits, ASICS, I/O circuits, and so on. In embodiments, the first circuit and the second circuit comprise a first chiplet and a second chiplet, respectively. In embodiments, the PWSI comprises an optical wafer-scale AI accelerator, wherein the first chiplet and the second chiplet are within a plurality of chiplets bonded to the front side of the PWSI, and wherein at least one chiplet within the plurality of chiplets comprises an artificial intelligence (AI) accelerator. The AI accelerator can be used for machine learning (ML), natural language processing (NLP), and the like. In other embodiments, the PWSI comprises an optical wafer-scale network switch, wherein the first chiplet and the second chiplet are within a plurality of chiplets bonded to the front side of the PWSI, and wherein at least one chiplet within the plurality of chiplets comprises a switching chiplet. The network switch can be used to provide data to compute-intensive applications such as AI, ML, image processing, etc.

The first circuit 810 sends electrical data 820 to the VCSEL 830. The VCSEL can include a single VCSEL (such as a first VCSEL), a plurality of VCSELs, a VCSEL array, and so on. In embodiments, the first VCSEL, when modulated, emits a degree of freedom modulated beam (DFMB) 840. The DFMB can include a modulated light polarization, a modulated light mode, a modulated light wavelength, a modulated intensity, etc. In a usage example, the DFMB can include two wavelengths, where one wavelength represents a logic one and the second wavelength represents a logic zero. In another usage example, two wavelengths can represent two different serial data streams. The first circuit can send data surface-emitting light sources that can be modulated, such as light emitting diodes (LEDs), laser diodes (LDs), and the like.

The DFMB 840 emitted by the first VCSEL is conveyed to an optical coupler 852. The apparatus 800 includes an optical coupler, wherein the optical coupler couples optically the DFMB to a first waveguide within the plurality of waveguides. The waveguide 850 can comprise an optical medium which can be a low loss optical medium appropriate for sending the DFMB. The optical medium can include an optical fiber. In a usage example, the optical medium can include a degree of freedom maintaining fiber. In embodiments, the coupling optically is based on a grating coupler. The grating coupler can include a periodic grating that can transfer the DFMB with low loss into the optical medium. In embodiments, the coupling optically is based on a bent waveguide. The bent waveguide can include a high containment region, where the high containment region minimizes loss from the DFMB. In embodiments, the coupling optically is based on an off-axis diffractive lens. The off-axis diffractive lens can be based on surfaces comprising different thicknesses or heights that diffract light, thereby bending and focusing the light onto an input aperture of a waveguide. In embodiments, the coupling optically is based on a mirror. In a usage example, the mirror can include a nano-imprint lithography mirror. Embodiments include angling the DFMB that was emitted by the first VCSEL, wherein the angling is based on a micro-optical element (MOE). The angling the DFMB can be used to complement an angle associated with the coupling the DFMB to the optical medium. The angling can also compensate for variations in a wafer or interposer across the surface of the wafer or interposer. In a usage example, the SFMB emitted by first VCSEL can be pre-angled to an angle such as 9.74 degrees or substantially 9.74 degrees, and a mirror such as a crystallographic etched mirror can include an angle such as 54.74 degrees or substantially 54.74 degrees. The combination of pre-angling and angling can enable coupling the WMB to a waveguide at an angle substantially normal to an entrance aperture of the waveguide.

The micro-optical element (MOE) can be based on one or more optical techniques. The MOE can comprise a micro lens. The micro lens can be coupled to a first surface-emitting light source such as the first VCSEL, a laser diode (LD), etc. The micro lens can pre-angle the emitted light. The MOE can comprise a diffractive optical element. The diffractive optical element can create a light phase profile that can focus, shape, or split the emitted light. The MOE can comprise a Fresnel lens. The Fresnel lens can use concentric grooves or rings to focus the emitted light. The MOE can comprise an asymmetric non-focusing optical device. The asymmetric non-focusing optical device can enable light to transmit through the device preferentially, where the light can pass through more easily in one direction than another direction. The asymmetric non-focusing optical device can couple light to an optical medium such as a waveguide and can suppress a portion of reflected light back to the surface-emitting light source.

The apparatus 800 includes an optical decoding element (ODE) 860, wherein the optical decoding element is further coupled to the first waveguide, and wherein the optical decoding element decodes the DFMB into the electrical data that was sent. The ODE can separate different degrees of freedom of light from the DFMB. The separated degrees of freedom can be based on light polarizations, light modes such as TEM modes, light wavelengths, etc. The separated degrees of freedom of light (e.g., optical data) can be decoded into electrical data that was sent by the first circuit. As described above and throughout, the ODE can accomplish decoding based on a plurality of decoding techniques. In embodiments, the optical decoding element comprises a grating coupler. The grating coupler can separate different polarizations of light. In other embodiments, the optical decoding element comprises a polarization filter. The polarization filter can enable a first light polarization to pass through the filter while reflecting a second light polarization. In further embodiments, the optical decoding element comprises a polarization multiplexor (PMUX). The PMUX can multiplex two or more light polarizations.

The apparatus 800 includes a second circuit 870 within the plurality of circuits, wherein the second circuit receives the electrical data that was decoded. The second circuit can receive the transmitted data that was sent by the first circuit. The first circuit and the second circuit can be located on a different or a common circuit board, a different or a common wafer, a different or a common interposer, a different or a common rack, and so on. The first circuit and the second circuit can be remotely located with respect to each other. “Remotely located” can include locating the first circuit and the second circuit in separate circuit boards or wafers, separate multiprocessors, separate data racks, separate data centers, and so on. As shown in the figure, the apparatus 800 includes a photonic wafer-scale interposer (PWSI) 880, wherein the PWSI includes a plurality of waveguides, and wherein a plurality of circuits and a plurality of vertical-cavity surface-emitting lasers (VCSELs) are bonded to a front side of the PWSI. The first circuit, the second circuit, and the first VCSEL can be coupled to a circuit board, included within a chip, etc. Recall that in embodiments, the first circuit and the second circuit comprise a first chiplet and a second chiplet, respectively. In a usage example, the first chiplet, the second chiplet, and the first VCSEL are within a plurality of chiplets bonded to a front side of a photonic wafer-scale interposer (PWSI). The PWSI further comprises a plurality of waveguides and a plurality of through-silicon vias (TSVs). The optical medium comprises a waveguide within the plurality of waveguides.

The PWSI can enable high-speed communication between and among chiplets and VCSELs coupled to the PWSI. The PWSI can be configured to accomplish a variety of processing tasks. In embodiments, the PWSI comprises an optical wafer-scale AI accelerator, wherein one or more chiplets within the plurality of chiplets comprise one or more artificial intelligence (AI) accelerators. The AI accelerators can be used for training AI models and machine learning (ML) models, executing the AI models and the ML models, and the like. The AI models and ML models can be applied to processing applications such as video and image processing; audio processing and voice recognition; etc. In other embodiments, the PWSI comprises an optical wafer-scale network switch, wherein one or more chiplets within the plurality of chiplets comprise one or more switching chiplets. The optical wafer-scale network switch can be used for accessing and transferring large amounts of data such as data associated with training AI models and ML models. The optical wafer-scale network switch can transfer data to be processed by the trained models.

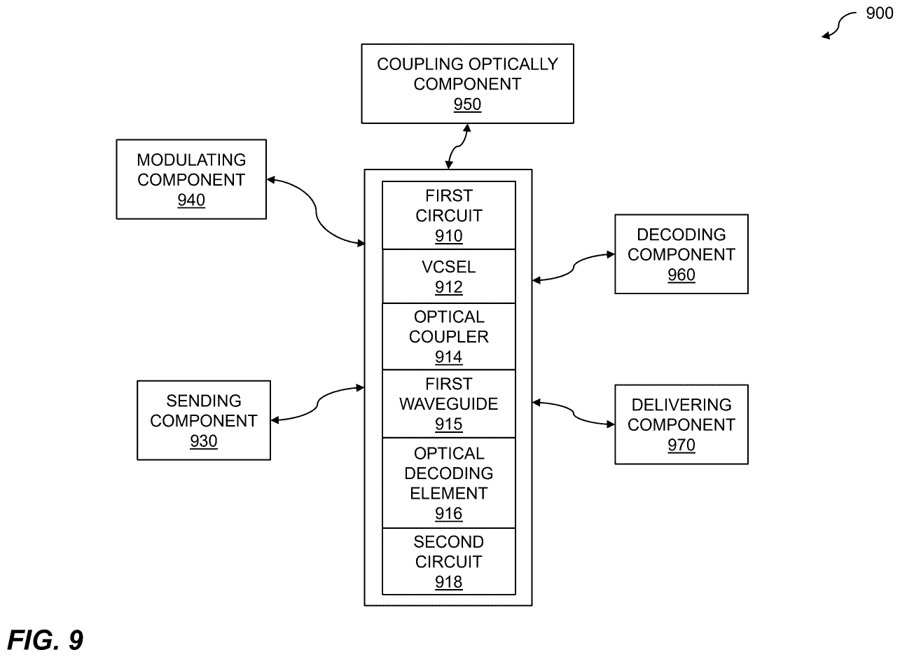

FIG. 9 is a system diagram for optical links with degree of freedom VCSEL modulation on a photonic wafer-scale interposer. Noted throughout, the degrees of freedom modulation can include polarization modulation, mode modulation, wavelength modulation, and so on. Optical links based on waveguides, optical fibers, etc. enable transmitting of data between circuits bonded to a photonic wafer-scale interposer (PWSI). The transmitting of data is accomplished using vertical-cavity surface-emitting lasers (VCSELs) to convert electrical data into optical data. In embodiments, the first circuit and the second circuit comprise a first chiplet and a second chiplet, respectively. The first circuit and the second circuit can be co-located on a circuit board, wafer, or interposer; located in different multiprocessors, boards, wafers, or interposers; located in different datacenters; and so on. The interposer can include a photonic wafer-scale interposer. A first circuit sends electrical data to a first vertical-cavity surface-emitting laser (VCSEL). The first VCSEL converts electrical data into optical data (e.g., light data) by modulating a light beam. The first VCSEL modulation includes modulating a degree of freedom (DoF) of a light beam emitted by the first VCSEL, wherein the emitted light beam comprises a degree of freedom modulated beam (DFMB). The DFMB is based on the electrical data that was sent. By coupling the modulated beam to an optical medium such as a waveguide, a fiber, and so on, the DFMB is sent via the optical medium to an optical decoding element (ODE). The ODE decodes the DFMB to electrical data. The electrical data that was decoded is delivered to the second circuit. The system enables transmitting data using optical links with degree of freedom VCSEL modulation on a photonic wafer-scale interposer (PWSI).

Disclosed is a system for transmitting data comprising: a photonic wafer-scale interposer (PWSI), wherein the PWSI includes a plurality of waveguides, and wherein a plurality of circuits and a plurality of vertical-cavity surface-emitting lasers (VCSELs) are bonded to a front side of the PWSI; a first circuit within the plurality of circuits, wherein the first circuit is coupled to a first VCSEL within the plurality of VCSELs; an optical coupler, wherein the optical coupler couples optically a light beam emitted from the first VCSEL to a first waveguide within the plurality of waveguides; an optical decoding element, wherein the optical decoding element is further coupled to the first waveguide; and a second circuit within the plurality of circuits; wherein the system is configured to: send electrical data, by the first circuit, to the first VCSEL; modulate a property of the first VCSEL, wherein the modulating includes emitting, by the first VCSEL, a degree of freedom modulated beam (DFMB), wherein the DFMB is based on the electrical data that was sent; couple optically the DFMB to the first waveguide; decode, by the optical decoding element, the DFMB into the electrical data; and deliver the electrical data that was decoded to the second circuit.

The system 900 includes a first circuit 910 within the plurality of circuits, wherein the first circuit is coupled to a first VCSEL within the plurality of VCSELs 912. The first circuit can include a chiplet within a plurality of chiplets. The chiplets can include processor chiplets, memory chiplets, AI accelerator chiplets, switching chiplets, I/O chiplets, and the like. Other surface-emitting light sources can also be used, such as a laser diode. The system 900 includes an optical coupler 914, wherein the optical coupler couples optically a light beam emitted from the first VCSEL to a first waveguide 915 within the plurality of waveguides. The light beam emitted by the first VCSEL includes a degree of freedom modulated beam (DFMB). The optical coupler can couple optically the emitted light beam to other optical media. The other optical media can include an optical fiber. In a usage example, the optical medium can comprise a degree of freedom maintaining fiber. Various optical elements can be used as an optical coupler to optically couple a degree of freedom modulated beam (DFMB) to the optical element. The coupling optically can be accomplished using the optical coupler. The optical coupler can comprise a grating coupler. The grating coupler can include a periodic grating that can transfer the DFMB with low loss into the optical medium. The optical coupler can comprise a mirror. In a usage example, the mirror can include a nano-imprint lithography mirror. Embodiments include angling the DFMB that was emitted by the first VCSEL, wherein the angling is based on a micro-optical element (MOE). The angling the polarization-modulated beam (PMB) can be used to complement an angle associated with the coupling the PMB to the optical medium.

The system 900 includes an optical decoding element (ODE) 916, wherein the optical decoding element is further coupled to the first waveguide. The ODE can distinguish among different degrees of freedom of light within the DFMB emitted by the first VCSEL. The ODE can separate different degrees of freedom including polarizations of light, modes of light, wavelengths of light, etc. The separated degrees of freedom of light can be decoded into electrical data that was sent by the first circuit. The ODE can accomplish decoding based on a plurality of decoding techniques. In embodiments, the optical decoding element comprises a grating coupler. The grating coupler can separate different polarizations, modes, and wavelengths in the DFMB from each other. The separated degrees of freedom of light can be sent to optical receivers that convert the optical data to electrical data. In a usage example, an optical receiver can comprise a photodiode. In a usage example, light emitted from the first VCSEL is modulated based on polarization. In embodiments, the optical decoding element comprises a polarization filter. A polarization filter can enable passage of light with a polarization that is compatible with the polarization filter, while substantially filtering out light with polarizations that are incompatible with the polarization filter. In further embodiments, the optical decoding element comprises a polarization multiplexor (PMUX). The PMUX separates light that includes two or more polarizations. In a usage example, the received light is separated into two or more beams, where each beam is based on a single polarization. In a usage example, a beam splitter can reflect light associated with a first polarization and transmit light associated with a second polarization.

The system 900 includes a second circuit 918. The second circuit can be a circuit substantially similar or different than the first circuit. The first circuit and the second circuit can comprise separate cores, cores on a wafer, chiplets, SoCs, ASICs, or any of the above on different wafers, interposers, and so on. The first circuit and the second circuit can comprise circuits within same or different chips, chiplets, SoCs, wafers, interposers, etc. The first circuit and the second circuit can comprise processors, multi-core processors, memory controllers, memory chips such as DDR or HBM chips, I/O chips, AI accelerators, switching chips, and so on. In embodiments, the first circuit and the second circuit comprise a first chiplet and a second chiplet, respectively. In a usage example, the first chiplet and the second chiplet comprise artificial intelligence (AI) accelerators. In a second usage example, the first chiplet and the second chiplet comprise switching chiplets. The second chiplet can be substantially different in function, type of chip, pin layout, etc. than the first chiplet. The second chiplet can be co-located within a plurality of chiplets that also includes the first chiplet. The second chiplet can be located remotely from the first chiplet.

The system 900 includes a sending component 930. The sending component is configured to send electrical data, by the first circuit, to the first VCSEL. The data can be sent by the first circuit to the first VCSEL using one or more of wires, interconnect, metal layers, etc. The metal layers can include metal layers within a circuit board, a wafer, an interposer, and so on. The metal layers, which enable interconnection between and among circuits, chiplets, and other elements, can be fabricated on or within a circuit board, wafer, or interposer such as the PWSI, etc. Using the metal layers can offer significant communications speed due to short wire lengths, and reduced “parasitics” such as resistance, capacitance, and inductance. The first VCSEL can emit light based on the sent data. The emitted light represents the data as optical data. The emitted light can be modulated.

The system 900 includes a modulating component 940. The modulating component is configured to modulate a property of the first VCSEL, wherein the modulating includes emitting, by the first VCSEL, a degree of freedom modulated beam (DFMB), wherein the DFMB is based on the electrical data that was sent. The DFMB can include a beam with a plurality of degrees of freedom such as polarizations, modes, and wavelengths. In a usage example, the DFMB can include two degrees of freedom, where one degree of freedom represents a logic one and the second degree of freedom represents a logic zero. In another usage example, two degrees of freedom can represent two different serial data streams. The first circuit can send data to other surface-emitting light sources that can be modulated, such as laser diodes (LDs). The DFMB can include an s-polarization. For s-polarization, the electric field of the modulated light is normal to a surface of incidence. The DFMB can include p-polarization. For p-polarization, the electric field of the modulated light is parallel to the surface of incidence. The DFMB can include a mode. A mode can include a transverse electromagnetic (TEM) mode. In a usage example, the TEM modes can include TEM₀₀, TEM₁₀, and TEM₀₁. The DFMB can include a wavelength. The wavelength can be based on a VCSEL chirp.

The system 900 includes a coupling optically component 950. The coupling optically component is configured to couple optically the DFMB to the first waveguide. The coupling optically can be used to couple the DFMB to other optical media such as an optic fiber. An optical medium can include a low loss optical medium appropriate for sending the DFMB. The optical medium can comprise a degree of freedom maintaining fiber. The coupling optically is accomplished using an optical coupler. A variety of optical couplers can be used, as described above. The optical coupler can include a grating coupler, a mirror, and so on.

The system 900 includes a decoding component 960. The decoding component is configured to decode, by the optical decoding element, the DFMB into the electrical data. The optical decoding element (ODE) can separate distinct degrees of freedom of light from the DFMB. The polarizations can be based on an s-polarization, a p-polarization, and so on. The modes can be based on the TEM modes, where the TEM modes can include TEM₀₀, TEM₁₀, and TEM₀₁. The wavelengths can be based on a VCSEL chirp. By adjusting carrier density by injecting current, a VCSEL emitted beam wavelength can be adjusted. The separated degrees of freedom of light, which are based on optical data, can be decoded into electrical data. The decoded electrical data is the data that was sent by the first circuit. As described above and throughout, the ODE can accomplish decoding based on a plurality of decoding techniques, such as a grating coupler, a polarization filter, a polarization mux, and so on.

The system 900 includes a delivering component 970. The delivering component is configured to deliver the electrical data that was decoded to the second circuit. The electrical data can be delivered by the delivering component to the second circuit using wire, interconnect, metal layers, fiberoptic cable, and so on. The metal layers can include metal layers within a circuit board, a wafer, an interposer, a PWSI, and so on. The metal layers, which enable interconnection between and among circuits, chiplets and other elements, can be fabricated on or within a board, wafer, interposer, etc. As was the case for sending the data from the first circuit to the VCSEL, using the metal layers can offer significant communications speed due to short wire lengths, and reduced “parasitics” such as resistance, capacitance, and inductance. The second circuit can process the delivered data, forward the delivered data, etc.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for transmitting data comprising:
bonding, to a front side of a photonic wafer-scale interposer (PWSI), a plurality of circuits and a plurality of vertical-cavity surface-emitting lasers (VCSELs), wherein the PWSI includes a plurality of waveguides;
sending electrical data, by a first circuit within the plurality of circuits, to a first VCSEL within the plurality of VCSELs;
modulating a degree of freedom (DoF) of a light beam emitted by the first VCSEL, wherein the emitted light beam comprises a degree of freedom modulated beam (DFMB), wherein the DFMB is based on the electrical data that was sent;
coupling optically the DFMB to a waveguide within the plurality of waveguides, wherein the waveguide is further coupled to an optical decoding element;
decoding, by the optical decoding element, the DFMB into the electrical data; and
delivering the electrical data that was decoded to a second circuit within the plurality of circuits.

2. The method of claim 1 wherein at least one waveguide in the plurality of waveguides comprises a first distance, wherein the first distance is greater than an exposure, on the PWSI, of a single photomask reticle.

3. The method of claim 2 wherein the at least one waveguide is fabricated using a nanoimprint lithography (NIL) process.

4. The method of claim 1 wherein the degree of freedom comprises a polarization of the first VCSEL.

5. The method of claim 4 wherein the modulating is based on asymmetric current injection.

6. The method of claim 5 wherein the optical decoding element comprises a grating coupler.

7. The method of claim 5 wherein the optical decoding element comprises a polarization filter.

8. The method of claim 5 wherein the optical decoding element comprises a polarization multiplexor (PMUX).

9. The method of claim 4 wherein the first VCSEL includes a ferroelectric liquid crystal layer (FLC).

10. The method of claim 1 wherein the degree of freedom comprises a mode of the first VCSEL.

11. The method of claim 10 wherein the modulating comprises altering current to the first VCSEL.

12. The method of claim 11 wherein the first VCSEL comprises a multimodal VCSEL.

13. The method of claim 11 wherein the first VCSEL comprises an inverted aperture VCSEL.

14. The method of claim 10 wherein a fundamental mode of the first VCSEL comprises a higher order mode than a non-fundamental mode.

15. The method of claim 1 wherein the degree of freedom comprises a wavelength of the first VCSEL.

16. The method of claim 15 wherein the modulating comprises injecting current into the first VCSEL.

17. The method of claim 16 wherein the modulating is based on VCSEL chirp.

18. The method of claim 16 wherein the injecting includes altering a bias current to the first VCSEL.

19. The method of claim 1 wherein the coupling optically is based on a mirror.

20. The method of claim 1 wherein the coupling optically is based on a bent waveguide.

21. The method of claim 1 wherein the coupling optically is based on an off-axis diffractive lens.

22. The method of claim 1 wherein the coupling optically is based on a grating coupler.

23. The method of claim 22 further comprising angling the DFMB that was emitted by the first VCSEL, wherein the angling is based on a micro-optical element (MOE).

24. The method of claim 1 wherein the first circuit and the second circuit comprise a first chiplet and a second chiplet, respectively.

25. An apparatus for transmitting data comprising:
a photonic wafer-scale interposer (PWSI), wherein the PWSI includes a plurality of waveguides, and wherein a plurality of circuits and a plurality of vertical-cavity surface-emitting lasers (VCSELs) are bonded to a front side of the PWSI;
a first circuit within the plurality of circuits, wherein the first circuit is coupled to a first VCSEL within the plurality of VCSELs, wherein the first circuit sends electrical data to the first VCSEL, and wherein the first VCSEL, when modulated, emits a degree of freedom modulated beam (DFMB);
an optical coupler, wherein the optical coupler couples optically the DFMB to a first waveguide within the plurality of waveguides;
an optical decoding element, wherein the optical decoding element is further coupled to the first waveguide, and wherein the optical decoding element decodes the DFMB into the electrical data that was sent; and
a second circuit within the plurality of circuits, wherein the second circuit receives the electrical data that was decoded.

26. The apparatus of claim 25 wherein the first circuit and the second circuit comprise a first chiplet and a second chiplet, respectively.

27. The apparatus of claim 26 wherein the PWSI comprises an optical wafer-scale AI accelerator, wherein the first chiplet and the second chiplet are within a plurality of chiplets bonded to the front side of the PWSI, and wherein at least one chiplet within the plurality of chiplets comprises an artificial intelligence (AI) accelerator.

28. The apparatus of claim 26 wherein the PWSI comprises an optical wafer-scale network switch, wherein the first chiplet and the second chiplet are within a plurality of chiplets bonded to the front side of the PWSI, and wherein at least one chiplet within the plurality of chiplets comprise a switching chiplet.

29. A system for transmitting data comprising:
a photonic wafer-scale interposer (PWSI), wherein the PWSI includes a plurality of waveguides, and wherein a plurality of circuits and a plurality of vertical-cavity surface-emitting lasers (VCSELs) are bonded to a front side of the PWSI;
a first circuit within the plurality of circuits, wherein the first circuit is coupled to a first VCSEL within the plurality of VCSELs;
an optical coupler, wherein the optical coupler couples optically a light beam emitted from the first VCSEL to a first waveguide within the plurality of waveguides;
an optical decoding element, wherein the optical decoding element is further coupled to the first waveguide; and
a second circuit within the plurality of circuits;
wherein the system is configured to:
send electrical data, by the first circuit, to the first VCSEL;
modulate a property of the first VCSEL, wherein the modulating includes emitting, by the first VCSEL, a degree of freedom modulated beam (DFMB), wherein the DFMB is based on the electrical data that was sent;
couple optically the DFMB to the first waveguide;
decode, by the optical decoding element, the DFMB into the electrical data; and
deliver the electrical data that was decoded to the second circuit.
